(19) United States
(12) Patent Application Publication
(10) Pub. No.: US 2026/0016550 A1
(43) Pub. Date: Jan. 15, 2026

(54) MAGNETIC SENSOR

(71) Applicant: TDK CORPORATION, Tokyo (JP)

(72) Inventors: Tetsuya HIRAKI, Tokyo (JP); Kazuya WATANABE, Tokyo (JP); Norikazu OTA, Tokyo (JP)

(73) Assignee: TDK CORPORATION, Tokyo (JP)

(21) Appl. No.: 19/254,272

(22) Filed: Jun. 30, 2025

(30) Foreign Application Priority Data
Jul. 10, 2024 (JP) 2024-111053

(51) Int. Cl. G01R 33/09; H10N 50/10; H10N 50/80

(52) U.S. Cl. CPC G01R 33/093; H10N 50/10; H10N 50/80

(57) ABSTRACT

A magnetic sensor includes a plurality of MR elements and a plurality of element arrays. Each of the plurality of element arrays includes multiple MR elements. The plurality of element arrays are connected in parallel by a first terminal and a second terminal. Each of the plurality of element arrays includes a first part, a second part, and a third part. Each of the first part and the third part extends in a first direction. The second part extends in a second direction. The number of MR elements included in the first part and the third part differs depending on an element array. The number of MR elements included in the second part is the same regardless of the element array.

### CROSS REFERENCE TO RELATED APPLICATIONS

This application claims the benefit of Japanese Priority Patent Application No. 2024-111053 filed on Jul. 10, 2024, the entire contents of which are incorporated herein by reference.

### BACKGROUND

The disclosure relates to a magnetic sensor including an element array including a plurality of magnetoresistive elements.

Magnetic sensors have been used for various applications in recent years. Examples of known magnetic sensors include one that uses a spin-valve magnetoresistive element provided on a substrate. The spin-valve magnetoresistive element includes a magnetization pinned layer having a magnetization whose direction is fixed, a free layer having a magnetization whose direction is variable depending on the direction of an applied magnetic field, and a gap layer located between the magnetization pinned layer and the free layer.

The specification of U.S. Patent Application Publication No. 2023/0324477 A1 discloses a magnetic sensor device including a plurality of TMR (tunnel magnetoresistive) elements connected in series by a plurality of upper metal layers and a plurality of lower metal layers. The TMR elements each have a free layer having a disk-like structure. In the free layer, a magnetization pattern having a closed magnetic flux, also called a vortex state, is spontaneously formed. In this magnetic sensor device, the plurality of upper metal layers and the plurality of lower metal layers are disposed so that the direction of the current flowing in the path through the plurality of TMR elements connected in series is in the Y direction in some parts and in the X direction in other parts.

In a magnetic sensor including a magnetoresistive element including a free layer having a vortex structure such as described in the specification of U.S. Patent Application Publication No. 2023/0324477 A1, it is desirable to reduce the diameter of the magnetoresistive element in order to expand the range in which the magnetoresistive element responds linearly to a change in the target magnetic field. However, doing so can reduce the sensitivity of the magnetoresistive element and increase the noise included in the detection signal generated by the magnetic sensor.

To suppress the noise, it is effective to increase the number of magnetoresistive elements. However, the resistance of magnetoresistive elements increases as the diameter of the magnetoresistive elements decreases. Therefore, when magnetoresistive elements with a smaller diameter are connected in series, Johnson noise increases and high-frequency noise characteristics deteriorate.

In general, an increase in the number of magnetoresistive elements results in size increase of magnetic sensors. As a result, the number of magnetic sensors made from a single wafer decrease and the cost of magnetic sensors increases. It is therefore desirable to increase the number of magnetoresistive elements while suppressing the size increase of magnetic sensors.

### SUMMARY

A magnetic sensor according to one embodiment of the disclosure includes: a plurality of magnetoresistive elements; a plurality of element arrays each including a wiring and multiple elements, the multiple elements being among the plurality of magnetoresistive elements and connected in series by the wiring; a first terminal; and a second terminal. The plurality of element arrays are connected in parallel with each other by the first terminal and the second terminal. Of the plurality of magnetoresistive elements, multiple elements are arrayed both in a first direction and a second direction that intersects the first direction. Each of the plurality of element arrays includes a first part, a second part, and a third part that are provided in this order from the first terminal side. Each of the first part and the third part extends in the first direction. The second part extends in the second direction. Among the multiple elements, the number of elements included in the first part differs depending on an element array to which the first part belongs among the plurality of element arrays. Among the multiple elements, the number of elements included in the second part is the same regardless of an element array to which the second part belongs among the plurality of element arrays. Among the multiple elements, the number of elements included in the third part differs depending on an element array to which the third part belongs among the plurality of element arrays.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a plan view showing a magnetic sensor according to a first example embodiment of the disclosure.

FIG. 2 is a circuit diagram showing a circuit configuration of the magnetic sensor according to the first example embodiment of the disclosure.

FIG. 3 is a plan view showing first through fourth resistor sections in the first example embodiment of the disclosure.

FIG. 4 is a plan view showing the first resistor section in the first example embodiment of the disclosure.

FIG. 5 is a plan view showing an element array in the first example embodiment of the disclosure.

FIG. 6 is a plan view showing a plurality of magnetoresistive elements, a plurality of lower electrodes, and a plurality of upper electrodes in the first example embodiment of the disclosure.

FIG. 7 is a side view showing a portion of the element array in the first example embodiment of the disclosure.

FIG. 8 is a side view showing an inactive magnetoresistive element in the first example embodiment of the disclosure.

FIG. 9 is a perspective view showing a magnetoresistive element in the first example embodiment of the disclosure.

FIG. 10 is a plan view showing a free layer of the magnetoresistive element in the first example embodiment of the disclosure.

FIG. 11 is a plan view showing the free layer when a target magnetic field is applied to the magnetoresistive element in the first example embodiment of the disclosure.

FIG. 12 is a plan view showing the free layer when the target magnetic field is applied to the magnetoresistive element in the first example embodiment of the disclosure.

FIG. 13 is a plan view showing a first resistor section in a first modification example of the magnetic sensor according to the first example embodiment of the disclosure.

FIG. 14 is a plan view showing a first resistor section in a second modification example of the magnetic sensor according to the first example embodiment of the disclosure.

FIG. 15 is a plan view showing a first resistor section in a third modification example of the magnetic sensor according to the first example embodiment of the disclosure.

FIG. 16 is a plan view showing a first resistor section in a fourth modification example of the magnetic sensor according to the first example embodiment of the disclosure.

FIG. 17 is a side view showing a portion of an element array in a fifth modification example of the magnetic sensor according to the first example embodiment of the disclosure.

FIG. 18 is a plan view showing a resistor section and an electrode layer in a sixth modification example of the magnetic sensor according to the first example embodiment of the disclosure.

FIG. 19 is a plan view showing a resistor section and an electrode layer in a seventh modification example of the magnetic sensor according to the first example embodiment of the disclosure.

FIG. 20 is a circuit diagram showing a circuit configuration of a magnetic sensor according to a second example embodiment of the disclosure.

FIG. 21 is a plan view showing first and second resistor sections in the second example embodiment of the disclosure.

FIG. 22 is a plan view showing a magnetic sensor according to a third example embodiment of the disclosure.

FIG. 23 is a plan view showing a first resistor section in the third example embodiment of the disclosure.

FIG. 24 is a plan view showing a first resistor section in a modification example of the magnetic sensor according to the third example embodiment of the disclosure.

FIG. 25 is a plan view showing a magnetic sensor according to a fourth example embodiment of the disclosure.

FIG. 26 is a circuit diagram showing a circuit configuration of the magnetic sensor according to the fourth example embodiment of the disclosure.

FIG. 27 is a plan view showing first and second auxiliary resistor sections in the fourth example embodiment of the disclosure.

FIG. 28 is a plan view showing the first auxiliary resistor section of a first resistor section in the fourth example embodiment of the disclosure.

FIG. 29 is a circuit diagram showing a circuit configuration of a magnetic sensor according to a fifth example embodiment of the disclosure.

FIG. 30 is a plan view showing first and second resistor sections in the fifth example embodiment of the disclosure.

FIG. 31 is a plan view showing a magnetic sensor according to a sixth example embodiment of the disclosure.

FIG. 32 is a circuit diagram showing a circuit configuration of the magnetic sensor according to the sixth example embodiment of the disclosure.

FIG. 33 is a plan view showing first through eighth resistor sections in the sixth example embodiment of the disclosure.

FIG. 34 is a cross-sectional view showing a magnetic sensor according to a seventh example embodiment of the disclosure.

### DETAILED DESCRIPTION

An object of the disclosure is to provide a magnetic sensor capable of increasing the number of magnetoresistive elements while suppressing the degradation of high-frequency noise characteristics and suppressing the size increase of the magnetic sensor.

In the following, some example embodiments and modification examples of the disclosure are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

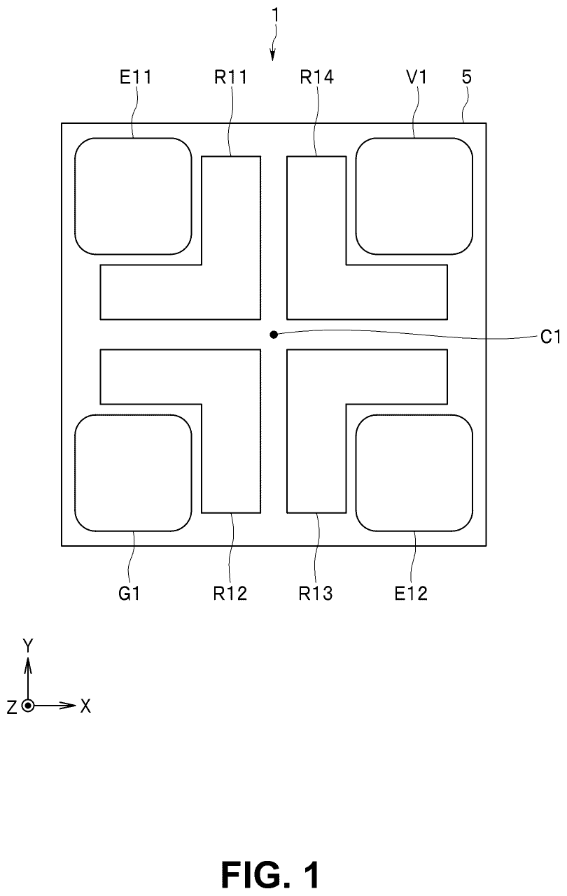

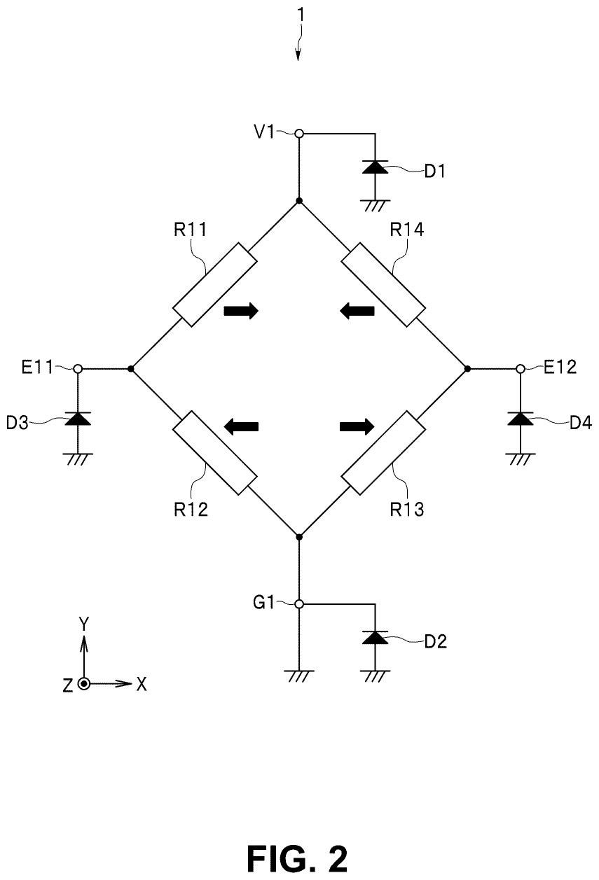

A schematic configuration of a magnetic sensor according to a first example embodiment of the disclosure will initially be described with reference to FIGS. 1 and 2. FIG. 1 is a plan view showing a magnetic sensor 1 according to the example embodiment. FIG. 2 is a circuit diagram showing a circuit configuration of the magnetic sensor 1 according to the example embodiment.

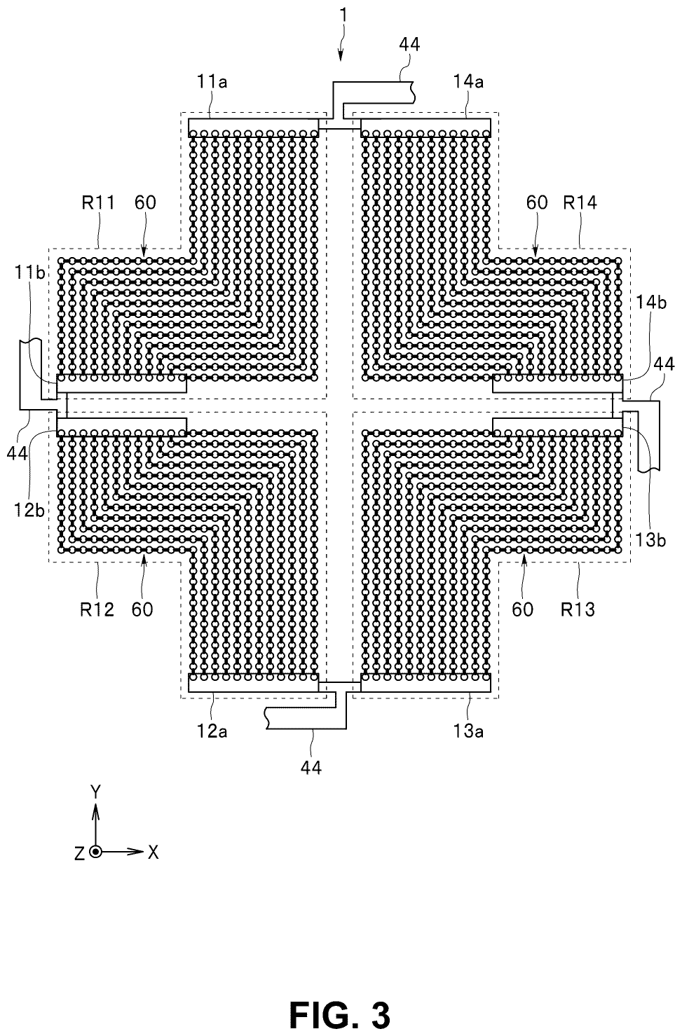

The magnetic sensor 1 in the example embodiment includes a plurality of magnetoresistive elements (hereinafter referred to as MR elements) 20. Each of the MR elements 20 is configured such that its resistance changes in response to a target magnetic field, which is the magnetic field to be detected by the magnetic sensor 1. Note that the MR elements 20 are shown in FIG. 3 and other figures to be described later.

The magnetic sensor 1 may further include a power supply terminal V1, a ground terminal G1, a first output terminal E11, a second output terminal E12, a first resistor section R11, a second resistor section R12, a third resistor section R13, and a fourth resistor section R14. The power supply terminal V1, the ground terminal G1, the first output terminal E11, and the second output terminal E12 are each constituted of an electrode layer formed of a conductive material. Each of the first through fourth resistor sections R11 to R14 includes multiple MR elements 20 among the plurality of MR elements 20.

As shown in FIG. 2, the first resistor section R11 may be provided between the power supply terminal V1 and the first output terminal E11 in a circuit configuration. The second resistor section R12 may be provided between the ground terminal G1 and the first output terminal E11 in the circuit configuration. The third resistor section R13 may be provided between the ground terminal G1 and the second output terminal E12 in the circuit configuration. The fourth resistor section R14 may be provided between the power supply terminal V1 and the second output terminal E12 in the circuit configuration. Note that in this application, the expression “in a (the) circuit configuration” is used to indicate a layout in a circuit diagram and not a layout in a physical configuration.

A voltage or current of a specific magnitude is applied to the power supply terminal V1. The ground terminal G1 is connected to the ground.

The magnetic sensor 1 further includes diodes D1, D2, D3, and D4. A cathode of the diode D1 is connected to the power supply terminal V1. A cathode of the diode D2 is connected to the ground terminal G1. A cathode of the diode D3 is connected to the first output terminal E11. A cathode of the diode D4 is connected to the second output terminal E12. Respective anodes of the diodes D1, D2, D3, and D4 are connected to the ground.

The magnetic sensor 1 further includes a substrate 5. The power supply terminal V1, the ground terminal G1, the first and second output terminals E11 and E12, the first through fourth resistor sections R11 to R14, and the diodes D1 to D4 are provided on the substrate 5.

Now, as shown in FIG. 1, an X direction, a Y direction, and a Z direction are defined. The X, Y, and Z directions are orthogonal to one another. The opposite directions to the X, Y, and Z directions are defined as −X, −Y, and −Z directions, respectively. In particular, in the example embodiment, one direction perpendicular to the surface of the substrate 5 is defined as the Z direction.

Hereinafter, the term “above” refers to positions located forward of a reference position in the Z direction, and “below” refers to positions opposite to the “above” positions with respect to the reference position. For each component of the magnetic sensor 1, the term “top surface” refers to a surface of the component lying at the end thereof in the Z direction, and “bottom surface” refers to a surface of the component lying at the end thereof in the −Z direction. The expression “when viewed in a specific direction (e.g., the Z direction)” means that an object is viewed in a position away in the specific direction or in one direction parallel to the specific direction.

FIG. 1 shows an example of an arrangement of the first through fourth resistor sections R11 to R14. The first resistor section R11 and the third resistor section R13 may be in a positional relationship in which, as viewed in the Z direction, the first resistor section R11 rotated 180° around a specific point C1 on the substrate 5 overlaps the third resistor section R13. The second resistor section R12 and the fourth resistor section R14 may be in a positional relationship in which, as viewed in the Z direction, the second resistor section R12 rotated 180° around the specific point C1 overlaps the fourth resistor section R14. The specific point C1 may be the center of gravity of the surface of the substrate 5 when viewed in the Z direction.

The second resistor section R12 is disposed symmetrically with respect to the first resistor section R11 about the XZ plane including the specific point C1. The fourth resistor section R14 is disposed symmetrically with respect to the third resistor section R13 about the XZ plane including the specific point C1.

The power supply terminal V1 is disposed in the vicinity of the fourth resistor section R14, and in the vicinity of a corner portion that exists at a position where a side surface of the substrate 5 located at an end thereof in the X direction intersects a side surface of the substrate 5 located at an end thereof in the Y direction. The ground terminal G1 is disposed in the vicinity of the second resistor section R12, and in the vicinity of a corner portion that exists at a position where a side surface of the substrate 5 located at an end thereof in the −X direction intersects a side surface of the substrate 5 located at an end thereof in the −Y direction. The first output terminal E11 is disposed in the vicinity of the first resistor section R11, and in the vicinity of a corner portion that exists at a position where the side surface of the substrate 5 located at an end thereof in the −X direction intersects the side surface of the substrate 5 located at an end thereof in the Y direction. The second output terminal E12 is disposed in the vicinity of the third resistor section R13, and in the vicinity of a corner portion that exists at a position where the side surface of the substrate 5 located at an end thereof in the X direction intersects the side surface of the substrate 5 located at an end thereof in the −Y direction.

Note that the arrangement of the power supply terminal V1, the ground terminal G1, the first output terminal E11, the second output terminal E12, and the first through fourth resistor sections R11 to R14 is not limited to the example shown in FIG. 1. For example, the first through fourth resistor sections R11 to R14 may be disposed in a specific order in a direction parallel to the X direction or in a direction parallel to the Y direction.

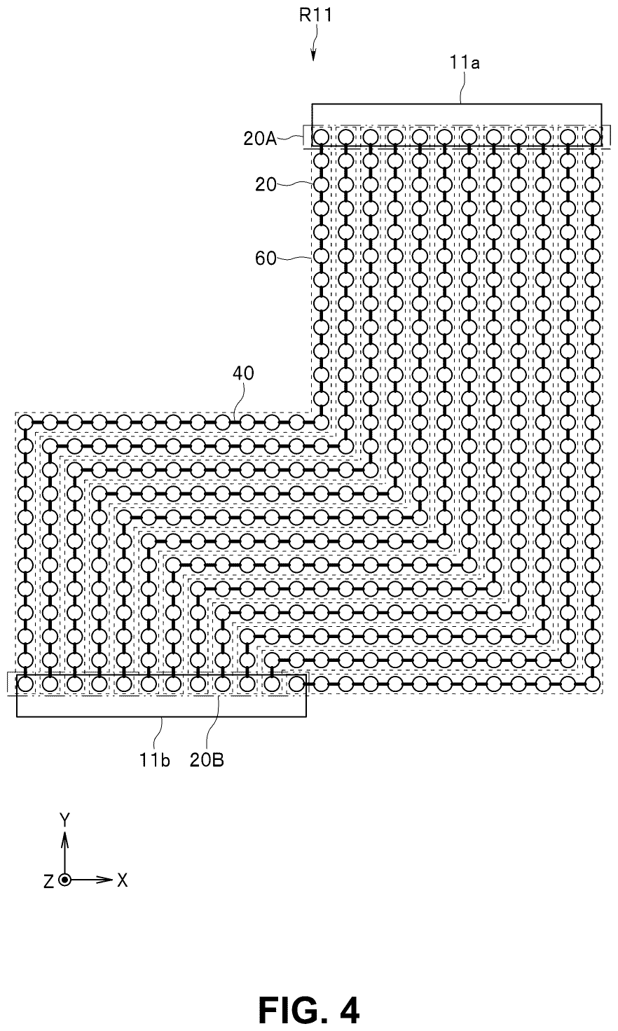

Next, a specific structure of the magnetic sensor 1 will be described in detail with reference to FIGS. 1, 3, and 4. FIG. 3 is a plan view showing the first through fourth resistor sections R11 to R14. FIG. 4 is a plan view showing the first resistor section R11. In FIGS. 3 and 4, a plurality of circles represent the plurality of MR elements 20.

Each of the first through fourth resistor sections R11 to R14 may include a plurality of element arrays 60, a first terminal, and a second terminal. Each of the plurality of element arrays 60 includes a wiring 40 and the multiple MR elements 20 connected in series by the wiring 40 among the plurality of MR elements 20.

In each of the first through fourth resistor sections R11 to R14, the plurality of element arrays 60 are connected in parallel with each other by the first terminal and the second terminal. Hereinafter, the first terminal and the second terminal of the first resistor section R11 will be denoted by the reference numerals 11a and 11b, respectively; the first terminal and the second terminal of the second resistor section R12 will be denoted by the reference numerals 12a and 12b, respectively; the first terminal and the second terminal of the third resistor section R13 will be denoted by the reference numerals 13a and 13b, respectively; and the first terminal and the second terminal of the fourth resistor section R14 will be denoted by the reference numerals 14a and 14b, respectively.

The first terminal 11a of the first resistor section R11 and the first terminal 14a of the fourth resistor section R14 are electrically connected to the power supply terminal V1. The first terminal 12a of the second resistor section R12 and the first terminal 13a of the third resistor section R13 are electrically connected to the ground terminal G1. The second terminal 11b of the first resistor section R11 and the second terminal 12b of the second resistor section R12 are electrically connected to the first output terminal E11. The second terminal 13b of the third resistor section R13 and the second terminal 14b of the fourth resistor section R14 are electrically connected to the second output terminal E12.

The magnetic sensor 1 may further include a plurality of wiring layers 44 each formed of a conductive material. The plurality of wiring layers 44 include a wiring layer 44 connecting the first terminals 11a and 14a to the power supply terminal V1, a wiring layer 44 connecting the first terminals 12a and 13a to the ground terminal G1, a wiring layer 44 connecting the second terminals 11b and 12b to the first output terminal E11, and a wiring layer 44 connecting the second terminals 13b and 14b to the second output terminal E12.

Note that, as mentioned below, the plurality of MR elements 20 include the plurality of MR elements 20 that constitute the plurality of element arrays 60, as well as the plurality of MR elements 20 that do not constitute the plurality of element arrays 60. FIG. 3 only shows the plurality of MR elements 20 that constitute the plurality of element arrays 60.

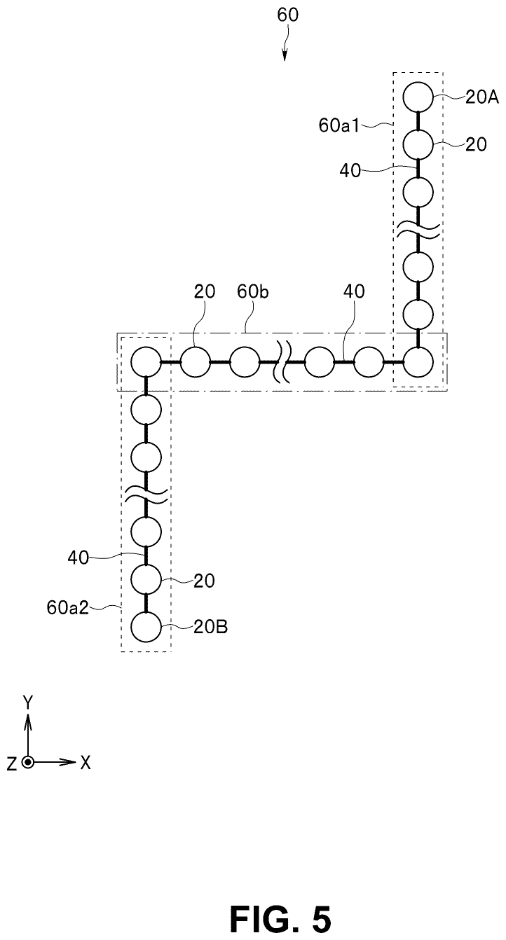

Next, with reference to FIGS. 4 and 5, an arrangement of the plurality of MR elements 20 and a configuration of an element array 60 will be described in detail. Here, description will be made by taking the first resistor section R11 as an example. FIG. 5 is a plan view showing one element array 60 included in the first resistor section R11.

On the substrate 5, of the plurality of MR elements 20, multiple elements are disposed both in a first direction and a second direction that intersects the first direction. In particular, in the example embodiment, of the plurality of MR elements 20, multiple elements are disposed both in the direction parallel to the Y direction and the direction parallel to the X direction.

The plurality of MR elements 20 may include a plurality of first MR elements 20A connected to the first terminal 11a and a plurality of second MR elements 20B connected to the second terminal 11b. The plurality of first MR elements 20A may be aligned in a row along the first direction or the second direction. The plurality of second MR elements 20B may be aligned in a row along the first direction or the second direction. In particular, in the example embodiment, the plurality of first MR elements 20A and the plurality of second MR elements 20B may both be aligned in a row along the direction parallel to the X direction.

The first resistor section R11 may include, as the plurality of element arrays 60, the element array 60 that meets a specific requirement and the element array 60 that does not meet the specific requirement. Initially, the plurality of element arrays 60 that meet the specific requirement will be described. In the following description, the element array 60 is one that meets the specific requirement, unless otherwise noted.

Each of the plurality of element arrays 60 includes a first part 60a1, a second part 60b, and a third part 60a2 that are provided in this order from the first terminal 11a side. The first part 60a1 includes a first MR element 20A. The third part 60a2 includes a second MR element 20B.

Each of the first part 60a1 and the third part 60a2 extends in a direction parallel to the first direction, i.e., the Y direction. The second part 60b extends in a direction parallel to the second direction, i.e., the X direction. In the first resistor section R11, the first part 60a1 extends in the −Y direction from the first terminal 11a to the second part 60b. The second part 60b extends in the −X direction from the first part 60a1 to the third part 60a2. The third part 60a2 extends in the −Y direction from the second part 60b to the second terminal 11b.

In each of the first part 60a1 and the third part 60a2, the plurality of MR elements 20 are aligned in the direction parallel to the Y direction. In the second part 60b, the plurality of MR elements 20 are aligned in the direction parallel to the X direction.

As shown in FIG. 5, the MR element 20 located at one end of the second part 60b belongs to both the first part 60a1 and the second part 60b. Thus, in the example embodiment, a portion of the first part 60a1 and a portion of the second part 60b overlap each other. The MR element 20 located at the other end of the second part 60b belongs to both the second part 60b and the third part 60a2. Thus, in the example embodiment, a portion of the second part 60b and a portion of the third part 60a2 overlap each other.

The number of the MR elements 20 included in the first part 60a1 differs depending on the element array 60 to which the first part 60a1 belongs. Now, focus is placed on any two element arrays 60 that are adjacent to each other with a spacing therebetween in FIG. 4. The difference between the number of the MR elements 20 included in the first part 60a1 belonging to one of the two element arrays 60 and the number of the MR elements 20 included in the first part 60a1 belonging to the other of the two element arrays 60 is one.

The number of the MR elements 20 included in the third part 60a2 differs depending on the element array 60 to which the third part 60a2 belongs. Now, focus is placed on any two element arrays 60 that are adjacent to each other with a spacing therebetween in FIG. 4. The difference between the number of the MR elements 20 included in the third part 60a2 belonging to one of the two element arrays 60 and the number of the MR elements 20 included in the third part 60a2 belonging to the other of the two element arrays 60 is one.

The sum of the number of the MR elements 20 included in the first part 60al and the number of the MR elements 20 included in the third part 60a2 may be the same regardless of the element array 60 to which both the first part 60a1 and the third part 60a2 belong. The number of the MR elements 20 included in the second part 60b is the same regardless of the element array 60 to which the second part 60b belongs. In particular, in the example embodiment, the number of the MR elements 20 included in each of the plurality of element arrays 60 is the same regardless of the element array 60. Note that each of the plurality of element arrays 60 is not provided with the MR element 20 that does not belong to any of the first part 60a1, the second part 60b, and the third part 60a2.

In the example shown in FIG. 4, the sum of the number of the MR elements 20 included in the first part 60a1 and the number of the MR elements 20 included in the third part 60a2 is 25. The number of the MR elements 20 included in the second part 60b is 13.

Next, the element array 60 that does not meet the specific requirement will be described. The element array 60 that does not meet the specific requirement includes the second part 60b but does not include one of the first part 60a1 and the third part 60a2. In the example shown in FIG. 4, one element array 60 that includes the first MR element 20A located on the outermost X-direction side and the second MR element 20B located on the outermost X-direction side does not include the third part 60a2. Therefore, this one element array 60 is the element array 60 that does not meet the specific requirement. The number of the MR elements 20 included in this one element array 60 is the same as the number of the MR elements 20 included in each of the other plurality of element arrays 60. The number of the MR elements 20 included in the second part 60b of this one element array 60 is the same as the number of the MR elements 20 included in the second part 60b of each of the other plurality of element arrays 60.

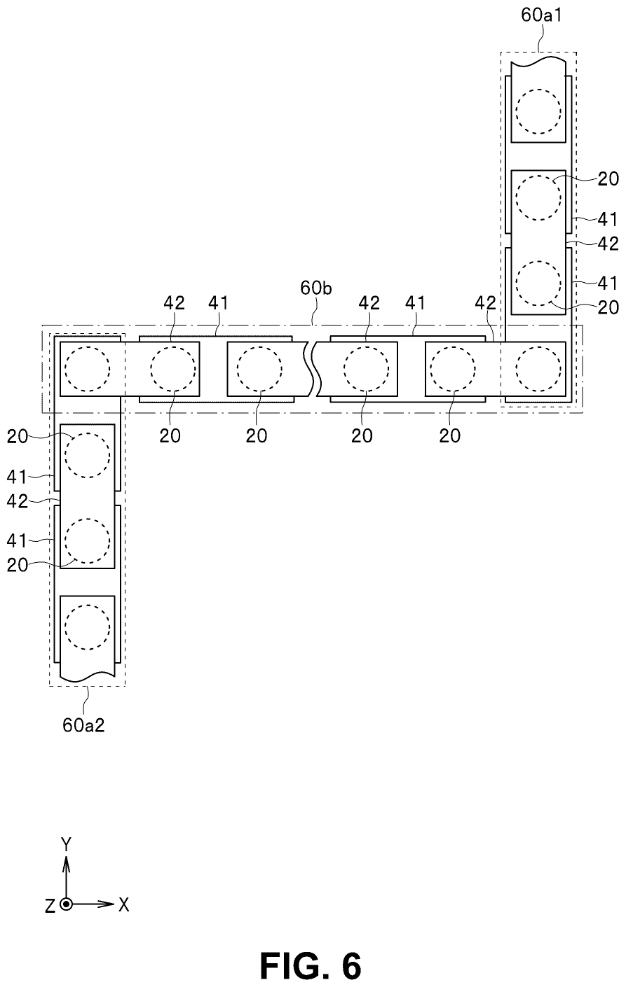

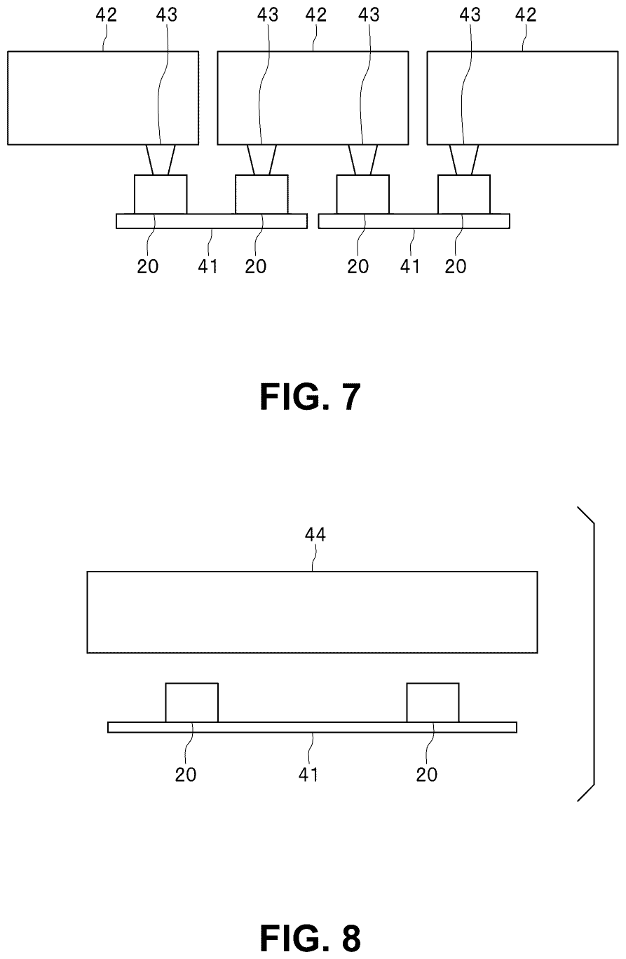

Referring now to FIGS. 6 and 7, a manner of connection of the plurality of MR elements 20 in each of the first part 60a1, the second part 60b, and the third part 60a2 will be described. FIG. 6 is a plan view showing the plurality of MR elements 20, a plurality of lower electrodes, and a plurality of upper electrodes. FIG. 7 is a side view showing a portion of the element array 60.

The wiring 40 may include a plurality of lower electrodes 41 and a plurality of upper electrodes 42. The individual lower electrodes 41 have an elongated shape. Two lower electrodes 41 that are adjacent to each other with a spacing therebetween have a gap therebetween. The MR elements 20 are disposed near both longitudinal ends of each lower electrode 41 on the top surface of each lower electrode 41. The individual upper electrodes 42 have an elongated shape, and are disposed so as to overlap the two adjacent MR elements 20 disposed on the two lower electrodes 41 that are adjacent to each other with a spacing therebetween, when viewed in the Z direction.

As shown in FIG. 7, the plurality of upper electrodes 42 may be disposed with a spacing from the plurality of MR elements 20 in the Z direction. The wiring 40 may further include a plurality of via electrodes 43, each formed of a conductive material. Each of the plurality of via electrodes 43 connects the MR element 20 to the upper electrode 42. With such a configuration, each of the plurality of element arrays 60 includes the plurality of MR elements 20 connected in series by the plurality of lower electrodes 41, the plurality of upper electrodes 42, and the plurality of via electrodes 43.

In the first part 60a1 and the third part 60a2, each of the plurality of lower electrodes 41 and the plurality of upper electrodes 42 extends in the direction parallel to the Y direction. In the second part 60b, each of the plurality of lower electrodes 41 and the plurality of upper electrodes 42 extends in the direction parallel to the X direction.

As shown in FIG. 7, the dimension of each of the plurality of upper electrodes 42 in a direction parallel to the Z direction may be larger than the dimension of each of the plurality of lower electrodes 41 in the direction parallel to the Z direction. In this case, the resistance of each of the plurality of upper electrodes 42 may be smaller than the resistance of each of the plurality of lower electrodes 41.

Note that the first terminal 11a may be disposed at the same position as the plurality of lower electrodes 41 in the direction parallel to the Z direction, or may be disposed at the same position as the plurality of upper electrodes 42 in the direction parallel to the Z direction. When the first terminal 11a is disposed at the same position as the plurality of upper electrodes 42, and the dimension of each of the plurality of upper electrodes 42 in the direction parallel to the Z direction is larger than the dimension of each of the plurality of lower electrodes 41 in the direction parallel to the Z direction, the resistance of the first terminal 11a is smaller than that when the first terminal 11a is disposed at the same position as the plurality of lower electrodes 41.

The above description of the first terminal 11a also applies to the second terminal 11b. Note that the second terminal 11b may be disposed at the same position as the first terminal 11a in the direction parallel to the Z direction, or may be disposed at a position different from the first terminal 11a in the direction parallel to the Z direction.

The number of the MR elements 20 included in each of the plurality of element arrays 60 may be even. When the number of the MR elements 20 is even, in each of the plurality of element arrays 60, the first MR element 20A and the MR element 20 adjacent to the first MR element 20A can be connected by the lower electrode 41, and the second MR element 20B and the MR element 20 adjacent to the second MR element 20B can be connected by the lower electrode 41. This allows the first terminal 11a to be disposed above the first MR element 20A, and the second terminal 11b to be disposed above the second MR element 20B.

Heretofore, description has been made by taking the first resistor section R11 as an example. The above description of the first resistor section R11 also applies to the second through fourth resistor sections R12 to R14. Note that as shown in FIG. 3, the first terminal 12a, the second terminal 12b, and the plurality of element arrays 60 of the second resistor section R12 may be symmetrical about the XZ plane with respect to the first terminal 11a, the second terminal 11b, and the plurality of element arrays 60 of the first resistor section R11.

As shown in FIG. 3, the first terminal 13a, the second terminal 13b, and the plurality of element arrays 60 of the third resistor section R13 may be symmetrical about the YZ plane with respect to the first terminal 12a, the second terminal 12b, and the plurality of element arrays 60 of the second resistor section R12. The first terminal 13a, the second terminal 13b, and the plurality of element arrays 60 of the third resistor section R13 may further be symmetrical (rotationally symmetrical) about the specific point C1 (see FIG. 1) with respect to the first terminal 11a, the second terminal 11b, and the plurality of element arrays 60 of the first resistor section R11.

As shown in FIG. 3, the first terminal 14a, the second terminal 14b, and the plurality of element arrays 60 of the fourth resistor section R14 may be symmetrical about the XZ plane with respect to the first terminal 13a, the second terminal 13b, and the plurality of element arrays 60 of the third resistor section R13. The first terminal 14a, the second terminal 14b, and the plurality of element arrays 60 of the fourth resistor section R14 may further be symmetrical about the YZ plane with respect to the first terminal 11a, the second terminal 11b, and the plurality of element arrays 60 of the first resistor section R11. The first terminal 14a, the second terminal 14b, and the plurality of element arrays 60 of the fourth resistor section R14 may further be symmetrical (rotationally symmetrical) about the specific point C1 (see FIG. 1) with respect to the first terminal 12a, the second terminal 12b, and the plurality of element arrays 60 of the second resistor section R12.

Next, an inactive MR element 20 will be described with reference to FIG. 8. FIG. 8 is a side view showing the inactive MR element 20. The inactive MR element 20 means the MR element 20 that is not involved in a detection signal generated by the magnetic sensor 1. The inactive MR element 20 is provided in an area other than the areas for forming the first through fourth resistor sections R11 to R14, and does not constitute the first through fourth resistor sections R11 to R14.

Here, of the plurality of MR elements 20, a plurality of elements that are disposed on the plurality of lower electrodes 41 and electrically connected to the plurality of upper electrodes 42 are referred to as a plurality of first-type elements. Of the plurality of MR elements 20, a plurality of elements that are disposed on the plurality of lower electrodes 41 and not electrically connected to the plurality of upper electrodes 42 are referred to as a plurality of second-type elements. The plurality of second-type elements are examples of the inactive MR element 20. The inactive MR element 20 shown in FIG. 8 is also an element of the second type.

Note that the lower electrode 41 may not be provided below the inactive MR element 20, as long as the requirement of not being involved in the detection signal generated by the magnetic sensor 1 is met.

The wiring layer 44 may be disposed in an area other than the areas for forming the first through fourth resistor sections R11 to R14. The wiring layer 44 may be disposed with a spacing from the plurality of MR elements 20 in the direction parallel to the Z direction. The wiring layer 44 may overlap a portion of the plurality of second-type elements (inactive MR elements 20) as viewed in the Z direction.

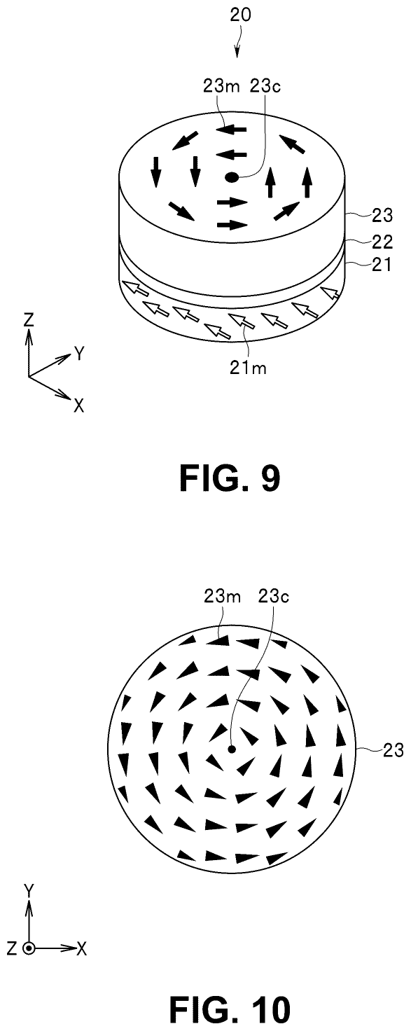

Next, a configuration of the MR element 20 will be described with reference to FIGS. 9 and 10. FIG. 9 is a perspective view showing the MR element 20. FIG. 10 is a plan view showing a free layer of the MR element 20.

The MR element 20 may include a magnetization pinned layer 21 having a magnetization 21m whose direction is fixed, a free layer 23, and a gap layer 22 located between the magnetization pinned layer 21 and the free layer 23. The material and shape of the free layer 23 are selected so that the free layer 23 has a magnetic vortex structure (also referred to as a vortex structure). The gap layer 22 is a tunnel barrier layer or a nonmagnetic conductive layer.

The free layer 23 has a cylindrical or substantially cylindrical shape. The free layer 23 has a magnetization 23m that is vortical about a center 23c of the magnetic vortex structure. When there is no magnetic field applied to the MR element 20, the center 23c of the magnetic vortex structure agrees with or substantially agrees with the axis of the cylinder. The center 23c of the magnetic vortex structure may move in response to a target magnetic field MF. In the example shown in FIGS. 9 and 10, the MR element 20 has a cylindrical overall shape.

The center 23c of the magnetic vortex structure moves if a component of the target magnetic field MF in a direction orthogonal to the Z direction is applied to the free layer 23. The free layer 23 may not saturate within the range of change in the strength of the component.

In the example embodiment, the magnetization 21m of the magnetization pinned layer 21 includes a component in the direction parallel to the X direction. Note that, if the magnetization 21m of the magnetization pinned layer 21 includes a component in a specific direction, the component in the specific direction may be the main component of the magnetization 21m of the magnetization pinned layer 21. Alternatively, the magnetization 21m of the magnetization pinned layer 21 may not include a component in a direction orthogonal to the specific direction. In the example embodiment, if the magnetization 21m of the magnetization pinned layer 21 includes a component in the specific direction, the direction of the magnetization 21m of the magnetization pinned layer 21 is the same or substantially the same as the specific direction.

The MR element 20 may further include an antiferromagnetic layer. The antiferromagnetic layer is formed of an antiferromagnetic material and is in exchange coupling with the magnetization pinned layer 21 to thereby pin the direction of the magnetization 21m of the magnetization pinned layer 21. Alternatively, the magnetization pinned layer 21 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled.

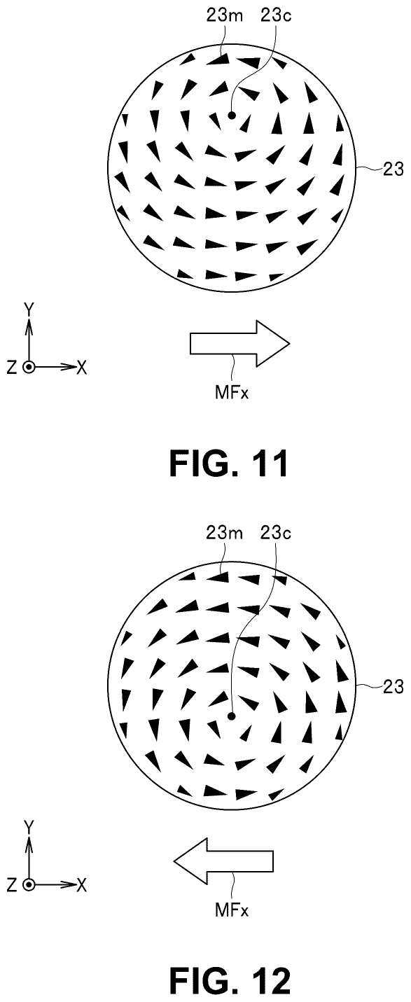

The resistance of the MR element 20 will now be described by using an example case where the direction of the magnetization 21m of the magnetization pinned layer 21 is the −X direction. FIGS. 11 and 12 show the free layer 23 when a magnetic field component MFx of the target magnetic field MF in the direction parallel to the X direction is applied to the free layer 23.

FIG. 11 shows the free layer 23 when the direction of the magnetic field component MFx is in the X direction. In such a case, the center 23c of the magnetic vortex structure moves due to the magnetic field component MFx, and the amount of the magnetization 23m oriented in the X direction becomes greater than that oriented in the −X direction. Here, the resistance of the MR element 20 increases.

FIG. 12 shows the free layer 23 when the direction of the magnetic field component MFx is in the −X direction. In such a case, the center 23c of the magnetic vortex structure moves due to the magnetic field component MFx, and the amount of the magnetization 23m oriented in the −X direction becomes greater than that oriented in the X direction. In such a case, the resistance of the MR element 20 decreases.

The amount of change in the resistance of the MR element 20 depends on the strength of the magnetic field component MFx. If the direction of the magnetic field component MFx is in the X direction, the amount of the magnetization 23m oriented in the X direction increases as the strength of the magnetic field component MFx increases. The resistance of the MR element 20 increases as the amount of the magnetization 23m oriented in the X direction increases. If the direction of the magnetic field component MFx is in the −X direction, the amount of the magnetization 23m oriented in the −X direction increases as the strength of the magnetic field component MFx increases. The resistance of the MR element 20 decreases as the amount of the magnetization 23m oriented in the −X direction increases. As the strength of the magnetic field component MFx increases, the resistance of the MR element 20 changes so that the amount of increase or the amount of decrease increases. As the strength of the magnetic field component MFx decreases, the resistance of the MR element 20 changes so that the amount of increase or the amount of decrease decreases. In particular, in the example embodiment, the relationship between the strength of the magnetic field component MFx and the resistance of the MR element 20 is linear or nearly linear, as long as the requirement that the free layer 23 does not saturate is met.

Next, with reference to FIG. 2, the direction of the magnetization 21m of the magnetization pinned layer 21 in each of the first through fourth resistor sections R11 to R14 will be described. The magnetization 21m of the magnetization pinned layer 21 of each of the plurality of MR elements 20 in the first resistor section R11 may include a component in a first magnetization direction. The magnetization 21m of the magnetization pinned layer 21 of each of the plurality of MR elements 20 in the second resistor section R12 may include a component in a second magnetization direction opposite to the first magnetization direction. The magnetization 21m of the magnetization pinned layer 21 of each of the plurality of MR elements 20 in the third resistor section R13 may include a component in the first magnetization direction. The magnetization 21m of the magnetization pinned layer 21 of each of the plurality of MR elements 20 in the fourth resistor section R14 may include a component in the second magnetization direction. In FIG. 2, two arrows drawn in the vicinity of the first and third resistor sections R11 and R13, respectively, indicate the first magnetization direction. In FIG. 2, two arrows drawn in the vicinity of the second and fourth resistor sections R12 and R14, respectively, indicate the second magnetization direction. In particular, in the example embodiment, the first magnetization direction is in the X direction and the second magnetization direction is in the −X direction.

Next, with reference to FIG. 2, at least one detection signal generated by the magnetic sensor 1 will be described. When the direction of the magnetic field component MFx is in the X direction, the resistance of each of the plurality of MR elements 20 of the first and third resistor sections R11 and R13 decreases, and the resistance of each of the plurality of MR elements 20 of the second and fourth resistor sections R12 and R14 increases, compared to when the magnetic field component MFx is not present. As a result, the resistance of each of the first and third resistor sections R11 and R13 decreases, and the resistance of each of the second and fourth resistor sections R12 and R14 increases.

When the direction of the magnetic field component is in the −X direction, the change in the resistance of each of the first through fourth resistor sections R11 to R14 is opposite to that in the above-mentioned case where the direction of the magnetic field component MFx is in the X direction.

In this way, when the direction and the strength of the magnetic field component MFx change, the resistance of each of the first through fourth resistor sections R11 to R14 changes so that either the resistance of each of the first and third resistor sections R11 and R13 increases and the resistance of each of the second and fourth resistor sections R12 and R14 decreases, or the resistance of each of the first and third resistor sections R11 and R13 decreases and the resistance of each of the second and fourth resistor sections R12 and R14 increases. As a result, the potential of the connection point between the first and second resistor sections R11 and R12, i.e., the potential of the first output terminal E11, and the potential of the connection point between the third and fourth resistor sections R13 and R14, i.e., the potential of the second output terminal E12 change. The magnetic sensor 1 may generate a signal corresponding to the potential of the first output terminal E11 and a signal corresponding to the potential of the second output terminal E12 as detection signals, respectively. Alternatively, the magnetic sensor 1 may generate a signal corresponding to the potential difference between the first output terminal E11 and the second output terminal E12 as a first detection signal. In this case, the magnetic sensor 1 may further include a differential amplifier (difference detector) that outputs the signal corresponding to the potential difference between the first output terminal E11 and the second output terminal E12 as a detection signal.

Next, a manufacturing method of the magnetic sensor 1 according to the example embodiment will be briefly described. The manufacturing method of the magnetic sensor 1 includes a process of forming the plurality of MR elements 20 on the substrate 5. In the process of forming the plurality of MR elements 20, first, a plurality of initial MR elements that will later become the plurality of MR elements 20 are formed. Each of the plurality of initial MR elements at least includes an initial magnetization pinned layer that will later become the magnetization pinned layer 21, the free layer 23, and the gap layer 22.

Next, the magnetization directions of the initial magnetization pinned layers are fixed in the foregoing specific direction using laser light and an external magnetic field in a specific direction. For example, the plurality of initial MR elements that will later become the plurality of MR elements 20 of the first and third resistor sections R11 and R13 are irradiated with laser light while an external magnetic field in the first magnetization direction (X direction) is applied thereto. When the initial MR elements include the antiferromagnetic layer, the irradiation of the laser light is performed so that the temperature of the plurality of initial MR elements irradiated with the laser light becomes equal to or higher than a blocking temperature of the antiferromagnetic layer. The temperature of the plurality of initial MR elements can be adjusted, for example, by the intensity and pulse width of the laser light. After the irradiation of the laser light, when the temperature of the plurality of initial MR elements becomes lower than the blocking temperature, the magnetization direction of the initial magnetization pinned layer is fixed in the first magnetization direction. This causes the initial magnetization pinned layer to become the magnetization pinned layer 21, and the plurality of initial MR elements to become the plurality of MR elements 20 of the first and third resistor sections R11 and R13.

In a plurality of other initial MR elements that will later become the plurality of MR elements 20 of the second and fourth resistor sections R12 and R14, the magnetization direction of the initial magnetization pinned layer in each of the plurality of other initial MR elements can be fixed in the second magnetization direction by setting the direction of the external magnetic field to the second magnetization direction (−X direction). In this way, the plurality of MR elements 20 of the second and fourth resistor sections R12 and R14 are formed.

Note that, for the inactive MR element 20, the magnetization direction of the initial magnetization pinned layer may or may not be fixed in the foregoing specific direction.

Next, effects of the magnetic sensor 1 according to the example embodiment will be described. In the example embodiment, each of the first through fourth resistor sections R11 to R14 includes the plurality of element arrays 60 connected in parallel with each other. Here, the number of MR elements included in one element array 60 is denoted by n, the number of element arrays 60 included in one resistor section is denoted by m, and the resistance of one MR element 20 is denoted by r. A resistance R of any one of the first through fourth resistor sections R11 to R14 is represented by the following equation (1).

$$R = nr / m \qquad ( 1 )$$

As understood from the equation (1), to make a comparison using the same number of the MR elements 20, according to the example embodiment, the resistance of each of the first through fourth resistor sections R11 to R14 can be reduced compared to that in the case where all the MR elements 20 are connected in series in each of the first through fourth resistor sections R11 to R14. According to the example embodiment, this enables increasing the number of the MR elements 20 while suppressing Johnson noise and suppressing the degradation of high-frequency noise characteristics.

According to the example embodiment, it is also possible to continue using the magnetic sensor 1 even if one of the plurality of element arrays 60 is disconnected. Note that the resistance R in this case is represented by the following equation (2).

$$R = nr / ( m - 1 ) \qquad ( 2 )$$

According to the example embodiment, even if one of the plurality of MR elements 20 is short-circuited, the amount of change in the resistance of each of the first through fourth resistor sections R11 to R14 can be reduced compared to that in the case where all the MR elements 20 are connected in series in each of the first through fourth resistor sections R11 to R14. Note that the resistance R in the case where one of the plurality of MR elements 20 is short-circuited is represented by the following equation (3).

$$R = n ( n - 1 ) r / ( m ( n - 1 ) + 1 ) \qquad ( 3 )$$

Incidentally, in order to increase the number of the MR elements 20 without increasing the size of the magnetic sensor 1, it is conceivable to cause the planar shape (shape viewed in the Z direction) of the first through fourth resistor sections R11 to R14 to match the shape and arrangement of the power supply terminal V1, the ground terminal G1, the first output terminal E11, and the second output terminal E12. To do so, it is conceivable to cause the shape of each of the plurality of element arrays 60 when viewed in the Z direction to be a shape bent to match the power supply terminal V1, the ground terminal G1, the first output terminal E11, and the second output terminal E12.

In the example embodiment, each of the plurality of element arrays 60 includes the first part 60a1 extending in the direction parallel to the Y direction, the second part 60b extending in the direction parallel to the X direction, and the third part 60a2 extending in the direction parallel to the Y direction. The number of the MR elements 20 included in the first part 60a1 differs depending on the element array 60 to which the first part 60a1 belongs, the number of the MR elements 20 included in the second part 60b is the same regardless of the element array 60 to which the second part 60b belongs, and the number of the MR elements 20 included in the third part 60a2 differs depending on the element array 60 to which the third part 60a2 belongs.

Now consider the case where the number of the MR elements 20 included in the second part 60b of each of the plurality of element arrays 60 is the same and the shape and the arrangement of the second part 60b when viewed in the Z direction are the same. If the number of the MR elements 20 included in the first part 60a1 is the same regardless of the element array 60 to which the first part 60a1 belongs, the plurality of first MR elements 20A are aligned along a direction intersecting both the X direction and the Y direction. In the first resistor section R11, the plurality of first MR elements 20A are aligned along a direction rotated 45° from the X direction towards the −Y direction. In this case, the MR element 20 located on the X-direction side of each of the plurality of first MR elements 20A cannot be used as the MR element 20 constituting the first resistor section R11. Therefore, in this case, the number of the MR elements 20 included in the first resistor section R11 is reduced. Also in this case, wasted space is created on the X-direction side of the plurality of first MR elements 20A.

The above description of the first part 60a1 also applies to the third part 60a2. In the first resistor section R11, the plurality of second MR elements 20B are aligned along a direction rotated 45° from the X direction towards the −Y direction. In this case, the MR element 20 located on the −X direction side of each of the plurality of second MR elements 20B cannot be used as the MR element 20 constituting the first resistor section R11. Therefore, in this case, the number of the MR elements 20 included in the first resistor section R11 is reduced. Also in this case, wasted space is created on the −X direction side of the plurality of second MR elements 20B.

In contrast, according to the example embodiment, by causing the number of the MR elements 20 included in the first part 60a1 to differ depending on the element array 60 to which the first part 60a1 belongs, and by causing the number of the MR elements 20 included in the third part 60a2 to differ depending on the element array 60 to which the third part 60a2 belongs, it is possible to increase the number of the MR elements 20 included in the first resistor section R11, and at the same time, suppress the creation of wasted space in the vicinity of the first resistor section R11. In other words, according to the example embodiment, it is possible to increase the number of the MR elements 20 while suppressing the size increase of the magnetic sensor 1.

The above description of the first resistor section R11 also applies to the second through fourth resistor sections R12 to R14.

From the above, according to the example embodiment, it is possible to increase the number of the MR elements 20 while suppressing the degradation of high-frequency noise characteristics and suppressing the size increase of the magnetic sensor 1.

In the example embodiment, both the first terminal and the second terminal extend in the direction parallel to the X direction, and both the plurality of first MR elements 20A and the plurality of second MR elements 20B are aligned along the direction parallel to the X direction. According to the example embodiment, this enables the plurality of element arrays 60 to be connected directly to the first terminal and the second terminal, thus omitting wiring to connect some of the plurality of element arrays 60 to the first terminal and the second terminal. According to the example embodiment, the number of the MR elements 20 in each of the plurality of element arrays 60 can be the same, and as a result, the magnitude of the voltage applied to each of the plurality of MR elements 20 can be the same.

In the example embodiment, the first resistor section R11 and the second resistor section R12 are disposed symmetrically about the XZ plane, the third resistor section R13 and the fourth resistor section R14 are disposed symmetrically about the XZ plane, the first resistor section R11 and the third resistor section R13 are disposed symmetrically (rotationally symmetrically) about the specific point C1, and the second resistor section R12 and the fourth resistor section R14 are disposed symmetrically (rotationally symmetrically) about the specific point C1. According to the example embodiment, this enables the influence when a stress is partially applied on the magnetic sensor 1 to be canceled out among the first through fourth resistor sections R11 to R14. As a result, according to the example embodiment, it is possible to suppress changes in the detection signal of the magnetic sensor 1 due to a partial stress.

### MODIFICATION EXAMPLES

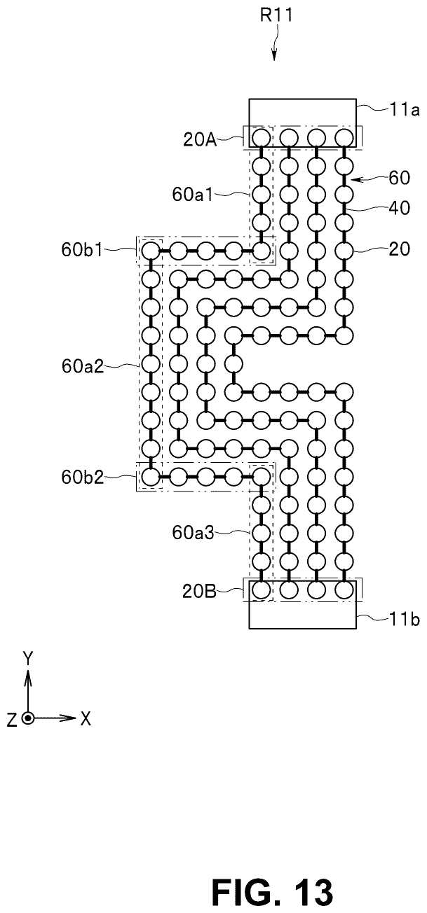

Next, first through seventh modification examples of the magnetic sensor 1 according to the example embodiment will be described. Initially, the first modification example will be described with reference to FIG. 13. FIG. 13 is a plan view showing the first resistor section R11 in the first modification example. In the first modification example, the structure of the plurality of element arrays 60 of the first resistor section R11 is different from the example shown in FIG. 4. In other words, in the first modification example, each of the plurality of element arrays 60 includes a part 60a1, a part 60b1, a part 60a2, a part 60b2, and a part 60a3 provided in this order from the first terminal 11a side. The part 60a1 includes the first MR element 20A. The part 60a3 includes the second MR element 20B.

Each of the parts 60a1 to 60a3 extends in the direction parallel to the Y direction. Each of the parts 60b1 and 60b2 extends in the direction parallel to the X direction. In the first modification example, in particular, each of the plurality of element arrays 60 extends from the first terminal 11a to the second terminal 11b, with the respective parts extending in the −Y direction, −X direction, −Y direction, X direction, and −Y direction, so that the position of the second terminal 11b in the direction parallel to the X direction is the same as the position of the first terminal 11a in the direction parallel to the X direction.

In each of the parts 60a1 to 60a3, the plurality of MR elements 20 are aligned in the direction parallel to the Y direction. In each of the parts 60b1 and 60b2, the plurality of MR elements 20 are aligned in the direction parallel to the X direction.

The parts 60a1 to 60a3 each satisfy the requirement for the number of the MR elements 20 in the first part 60a1 or the third part 60a2, described with reference to FIG. 4. The total number of the MR elements 20 included in the parts 60a1 to 60a3 is the same regardless of the element array 60 to which all the parts 60a1 to 60a3 belong.

The parts 60b1 and 60b2 each satisfy the requirement for the number of the MR elements 20 in the second part 60b, described with reference to FIG. 4. In the first modification example, the number of the MR elements 20 included in each of the plurality of element arrays 60 is the same regardless of the element array 60.

The above description of the first resistor section R11 also applies to the second through fourth resistor sections R12 to R14. The description of the first terminal, the second terminal, and the plurality of element arrays of each of the first through fourth resistor sections R11 to R14, described with reference to FIG. 3, also applies to the first through fourth resistor sections R11 to R14 of the first modification example.

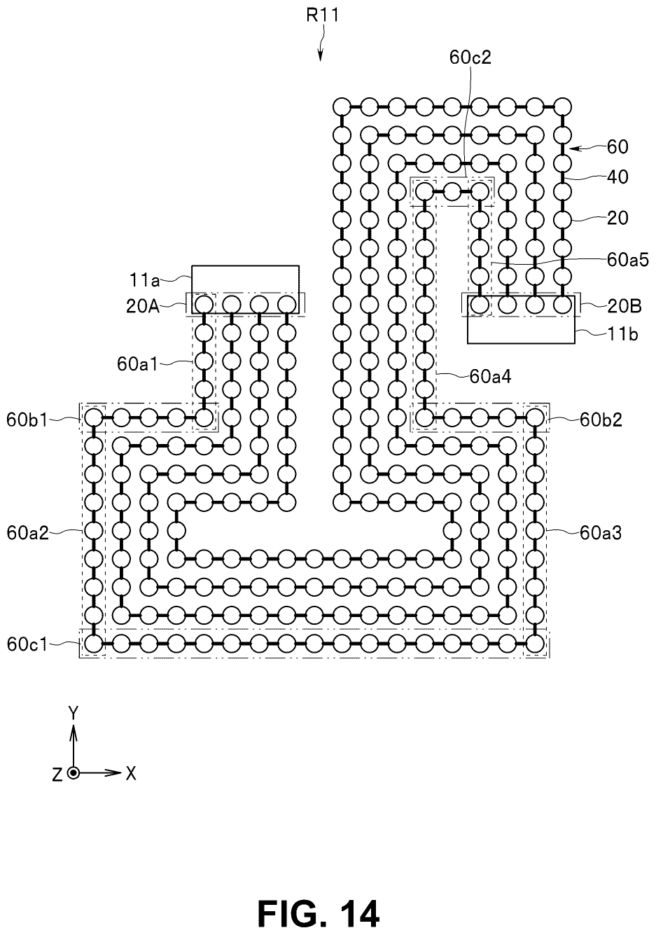

Next, the second modification example will be described with reference to FIG. 14. FIG. 14 is a plan view showing the first resistor section R11 in the second modification example. In the second modification example, the structure of the plurality of element arrays 60 of the first resistor section R11 is different from the example shown in FIG. 4. In other words, in the second modification example, each of the plurality of element arrays 60 includes the part 60a1, the part 60b1, the part 60a2, a part 60c1, the part 60a3, the part 60b2, a part 60a4, a part 60c2, and a part 60a5 provided in this order from the first terminal 11a side. The part 60a1 includes the first MR element 20A. The part 60a5 includes the second MR element 20B.

Each of the parts 60a1 to 60a5 extends in the direction parallel to the Y direction. Each of the parts 60b1, 60b2, 60cl, and 60c2 extends in the direction parallel to the X direction. In the second modification example, in particular, each of the plurality of element arrays 60 extends from the first terminal 11a to the second terminal 11b, with the respective parts extending in the −Y direction, −X direction, −Y direction, X direction, Y direction, −X direction, Y direction, X direction, and −Y direction, so that the positions of the plurality of second MR elements 20B in the direction parallel to the Y direction are the same as the positions of the plurality of first MR elements 20A in the direction parallel to the Y direction.

In each of the parts 60a1 to 60a5, the plurality of MR elements 20 are aligned in the direction parallel to the Y direction. In each of the parts 60b1, 60b2, 60cl, and 60c2, the plurality of MR elements 20 are aligned in the direction parallel to the X direction.

The parts 60a1 to 60a5, 60cl, and 60c2 each satisfy the requirement for the number of the MR elements 20 in the first part 60a1 or the third part 60a2, described with reference to FIG. 4. The total number of the MR elements 20 included in the parts 60a1 to 60a5, 60cl, and 60c2 is the same regardless of the element array 60 to which all the parts 60a1 to 60a5, 60cl, and 60c2 belong.

The parts 60b1 and 60b2 each satisfy the requirement for the number of the MR elements 20 in the second part 60b, described with reference to FIG. 4. In the second modification example, the number of the MR elements 20 included in each of the plurality of element arrays 60 is the same regardless of the element array 60.

The above description of the first resistor section R11 also applies to the second through fourth resistor sections R12 to R14. The description of the first terminal, the second terminal, and the plurality of element arrays of each of the first through fourth resistor sections R11 to R14, described with reference to FIG. 3, also applies to the first through fourth resistor sections R11 to R14 of the second modification example.

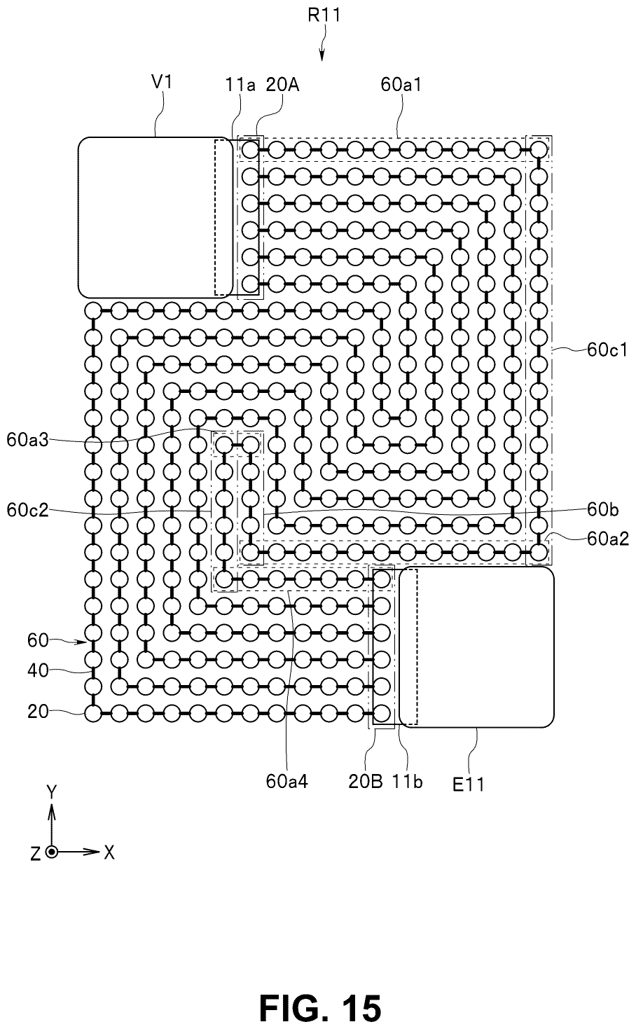

Next, the third modification example will be described with reference to FIG. 15. FIG. 15 is a plan view showing the first resistor section R11 in the third modification example. In the third modification example, the structure of the plurality of element arrays 60 of the first resistor section R11 is different from the example shown in FIG. 4. In other words, in the third modification example, each of the plurality of element arrays 60 includes the part 60a1, the part 60cl, the part 60a2, a part 60b, the part 60a3, the part 60c2, and the part 60a4 provided in this order from the first terminal 11a side. The part 60a1 includes the first MR element 20A. The part 60a4 includes the second MR element 20B.

Each of the parts 60a1 to 60a4 extends in the direction parallel to the X direction. Each of the parts 60b, 60cl, and 60c2 extends in the direction parallel to the Y direction. In the third modification example, each of the plurality of element arrays 60 extends from the first terminal 11a to the second terminal 11b, with the respective parts extending in the X direction, −Y direction, −X direction, Y direction, −X direction, −Y direction, and X direction.

In each of the parts 60a1 to 60a4, the plurality of MR elements 20 are aligned in the direction parallel to the X direction. In each of the parts 60b, 60cl, and 60c2, the plurality of MR elements 20 are aligned in the direction parallel to the Y direction.

The parts 60a1 to 60a4, 60c1, and 60c2 each satisfy the requirement for the number of the MR elements 20 in the first part 60a1 or the third part 60a2, described with reference to FIG. 4. The total number of the MR elements 20 included in the parts 60a1 to 60a4, 60cl, and 60c2 is the same regardless of the element array 60 to which all the parts 60a1 to 60a4, 60cl, and 60c2 belong.

The part 60b satisfies the requirement for the number of the MR elements 20 in the second part 60b, described with reference to FIG. 4. In the third modification example, the number of the MR elements 20 included in each of the plurality of element arrays 60 is the same regardless of the element array 60.

The above description of the first resistor section R11 also applies to the second through fourth resistor sections R12 to R14. The description of the first terminal, the second terminal, and the plurality of element arrays of each of the first through fourth resistor sections R11 to R14, described with reference to FIG. 3, also applies to the first through fourth resistor sections R11 to R14 of the third modification example.

Note that, in particular, in the third modification example, the first terminal 11a of the first resistor section R11 may be disposed so as to overlap the power supply terminal V1 when viewed in the Z direction. In a similar manner, the second terminal 11b of the first resistor section R11 may be disposed so as to overlap the first output terminal E11 when viewed in the Z direction.

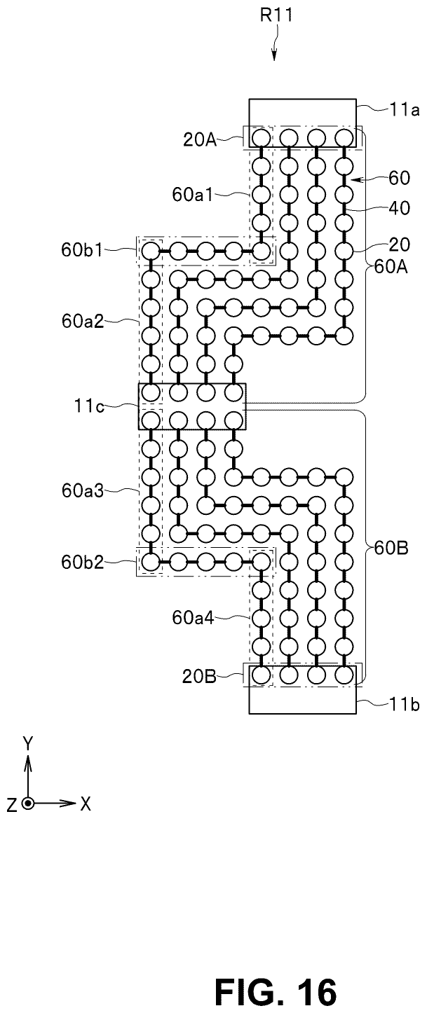

Next, the fourth modification example will be described with reference to FIG. 16. FIG. 16 is a plan view showing the first resistor section R11 in the fourth modification example. In the fourth modification example, the first resistor section R11 may further include a third terminal 11c. The plurality of element arrays 60 may include a part 60A where the plurality of element arrays 60 are connected in parallel by the first terminal 11a and the third terminal 11c, and a part 60B where the plurality of element arrays 60 are connected in parallel by the second terminal 11b and the third terminal 11c.

In the part 60A, each of the plurality of element arrays 60 includes the part 60a1, the part 60b1, and the part 60a2 provided in this order from the first terminal 11a side. In the part 60B, each of the plurality of element arrays 60 includes the part 60a3, the part 60b2, and the part 60a4 provided in this order from the third terminal 11c side. The part 60a1 includes the first MR element 20A. The part 60a4 includes the second MR element 20B.

Each of the parts 60a1 to 60a4 extends in the direction parallel to the Y direction. Each of the parts 60b1 and 60b2 extends in the direction parallel to the X direction. In the fourth modification example, in particular, each of the plurality of element arrays 60 extends from the first terminal 11a to the second terminal 11b, with the respective parts extending in the −Y direction, −X direction, −Y direction, −Y direction, X direction, and −Y direction, so that the position of the second terminal 11b in the direction parallel to the X direction is the same as the position of the first terminal 11a in the direction parallel to the X direction.

In each of the parts 60a1 to 60a4, the plurality of MR elements 20 are aligned in the direction parallel to the Y direction. In each of the parts 60b1 and 60b2, the plurality of MR elements 20 are aligned in the direction parallel to the X direction.

The parts 60a1 to 60a4 each satisfy the requirement for the number of the MR elements 20 in the first part 60a1 or the third part 60a2, described with reference to FIG. 4. The total number of the MR elements 20 included in the parts 60a1 to 60a4 is the same regardless of the element array 60 to which all the parts 60a1 to 60a4 belong.

The parts 60b1 and 60b2 satisfy the requirement for the number of the MR elements 20 in the second part 60b, described with reference to FIG. 4. In the fourth modification example, the number of the MR elements 20 included in each of the plurality of element arrays 60 is the same regardless of the element array 60.

To make a comparison using the same number of the MR elements 20 included in each of the plurality of element arrays 60, in the fourth modification example, it is possible to reduce the number of the MR elements 20 connected in series in each of the plurality of element arrays 60. This allows the resistance of the first resistor section R11 to be reduced.

The above description of the first resistor section R11 also applies to the second through fourth resistor sections R12 to R14. In other words, each of the second through fourth resistor sections R12 to R14 further includes a third terminal. In each of the second through fourth resistor sections R12 to R14, the plurality of element arrays 60 include a part where the element arrays 60 are connected in parallel by the first terminal and the third terminal, and a part where the element arrays 60 are connected in parallel by the second terminal and the third terminal.

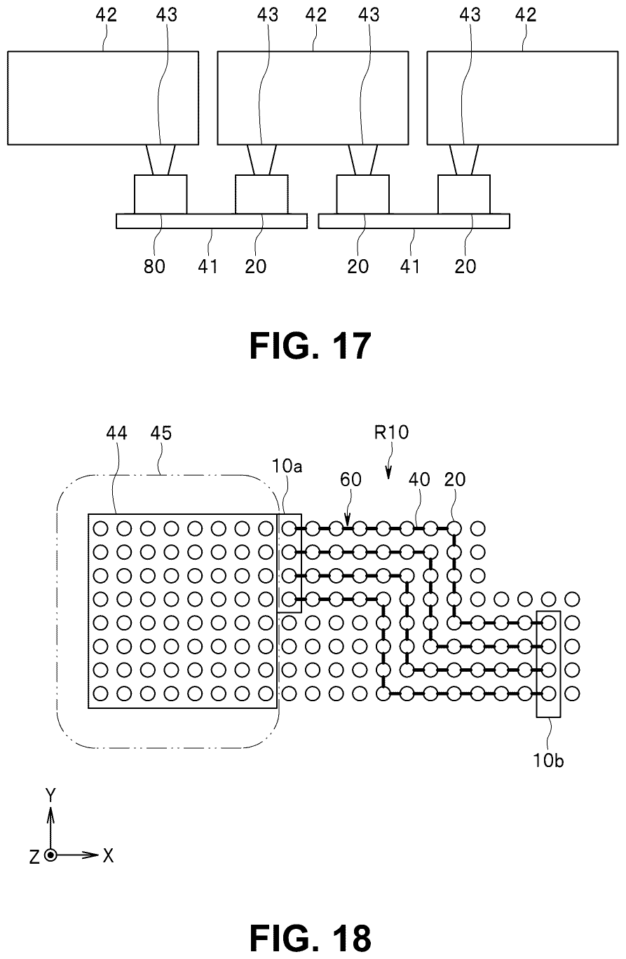

Next, the fifth modification example will be described with reference to FIG. 17. FIG. 17 is a side view showing a portion of the element array 60 in the fifth modification example. In the fifth modification example, the number of the multiple MR elements 20 included in each of the plurality of element arrays 60 is odd. Each of the plurality of element arrays 60 further includes a through-hole electrode 80. The shape of the through-hole electrode 80 may be similar to that of the MR element 20.

The arrangement of the through-hole electrode 80 in the element array 60 is the same as that of any one MR element 20 in the element array 60. For example, the through-hole electrode 80 may be provided to be connected to the first terminal or the second terminal, instead of to the first MR element 20A or the second MR element 20B. Alternatively, the through-hole electrode 80 may be provided in place of any one MR element 20 between the first MR element 20A and the second MR element 20B.

The through-hole electrode 80 is connected to one or two MR elements 20 that are adjacent to and spaced apart from the through-hole electrode 80, by the lower electrode 41, the upper electrode 42, and a via electrode 43.

In the fifth modification example, the total number of the plurality of MR elements 20 and the through-hole electrodes 80 in each of the plurality of element arrays 60 is even. Note that the number of through-hole electrodes 80 is not limited to one, but is only required to be odd.

Next, the sixth modification example will be described with reference to FIG. 18. FIG. 18 is a plan view showing a resistor section and an electrode layer in the sixth modification example. Here, any resistor section among the first through fourth resistor sections R11 to R14 is denoted by the reference numeral R10, a first terminal of the resistor section R10 is denoted by the reference numeral 10a, and a second terminal of the resistor section R10 is denoted by the reference numeral 10b. An electrode layer constituting any of the power supply terminal V1, the ground terminal G1, the first output terminal E11, and the second output terminal E12 is denoted by the reference numeral 45.

In FIG. 18, the plurality of MR elements 20 that are not connected to a plurality of wirings 40, i.e., the plurality of MR elements 20 that do not constitute the plurality of element arrays 60, represent a plurality of inactive MR elements 20. The plurality of inactive MR elements 20 may be the plurality of second-type elements that are disposed on the plurality of lower electrodes 41 and not electrically connected to the plurality of upper electrodes 42.

In the sixth modification example, the wiring layer 44 is disposed above the plurality of inactive MR elements 20 (the plurality of second-type elements). An electrode layer 45 is disposed above the plurality of inactive MR elements 20 and the wiring layer 44, and is electrically connected to the wiring layer 44. Of the plurality of inactive MR elements 20 disposed so as to overlap the electrode layer 45 when viewed in the Z direction, multiple elements may be arrayed both in the X direction and the Y direction.

The plurality of inactive MR elements 20 may not be electrically connected to the wiring layer 44. Alternatively, the plurality of inactive MR elements 20 may be electrically connected to the wiring layer 44 via a plurality of via electrodes (not shown). In this case, the plurality of inactive MR elements 20 are electrically connected to the electrode layer 45 via the plurality of via electrodes and the wiring layer 44.

When the plurality of inactive MR elements 20 are electrically connected to the electrode layer 45, the plurality of inactive MR elements 20 may be electrically connected to any of the diodes D1 to D4 shown in FIG. 2, via a plurality of lower electrodes (not shown) and a connection layer (not shown) formed of a conductive material.

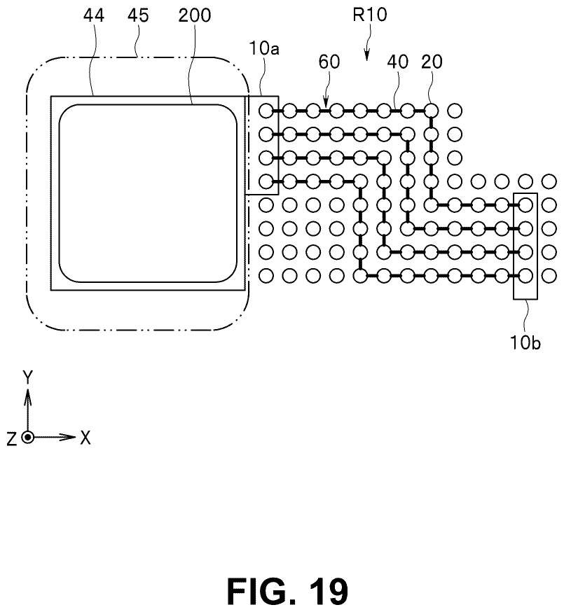

Next, the seventh modification example will be described with reference to FIG. 19. FIG. 19 is a plan view showing a resistor section and an electrode layer in the seventh modification example. The seventh modification example differs from the sixth modification example in the following respects. In the seventh modification example, the magnetic sensor 1 includes a stacked film 200 instead of the plurality of inactive MR elements 20 disposed so as to overlap the electrode layer 45 when viewed in the Z direction in the sixth modification example.

The stacked film 200 includes a first layer formed of the same magnetic layer as the magnetic layer forming the magnetization pinned layer 21 of the MR element 20, a second layer formed of the same nonmagnetic layer as the nonmagnetic layer forming the gap layer 22 of the MR element 20, and a third layer formed of the same magnetic layer as the magnetic layer forming the free layer 23 of the MR element 20.

The wiring layer 44 is disposed above a stacked film 200. The electrode layer 45 is disposed above the stacked film 200 and the wiring layer 44.

The stacked film 200 may not be electrically connected to the wiring layer 44. Alternatively, the stacked film 200 may be electrically connected to the wiring layer 44 via at least one via electrode (not shown). In this case, the stacked film 200 is electrically connected to the electrode layer 45 via at least one via electrode and the wiring layer 44.

When the stacked film 200 is electrically connected to the electrode layer 45, the stacked film 200 may be electrically connected to any of the diodes D1 to D4 shown in FIG. 2 via a connection layer (not shown) formed of a conductive material.

### Second Example Embodiment

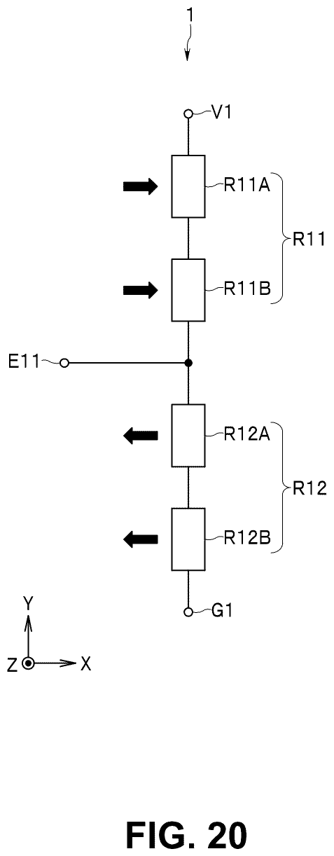

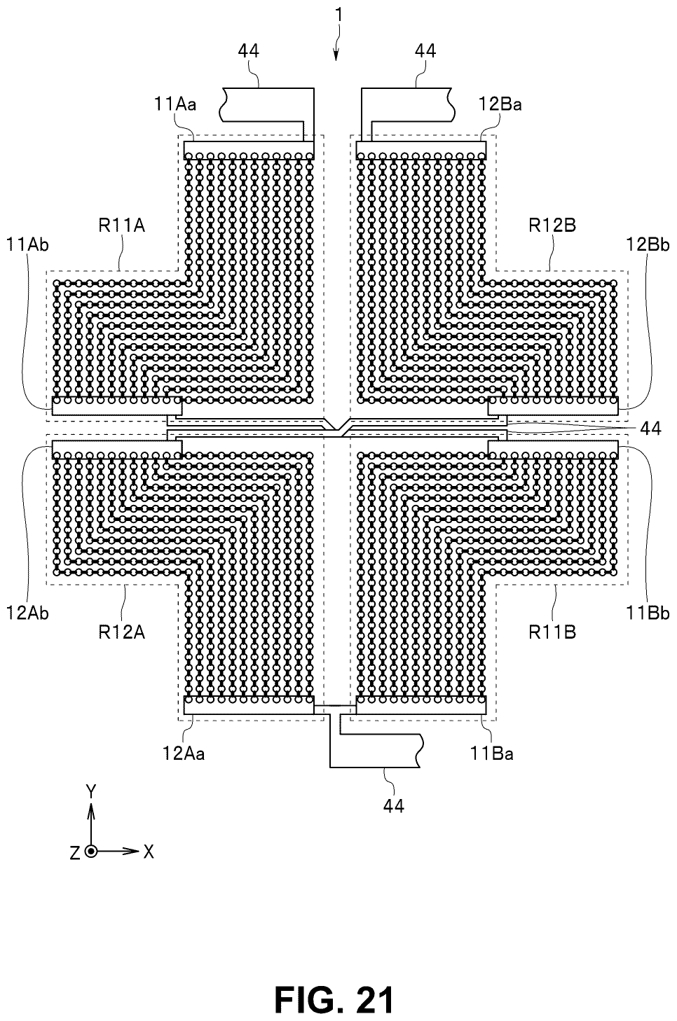

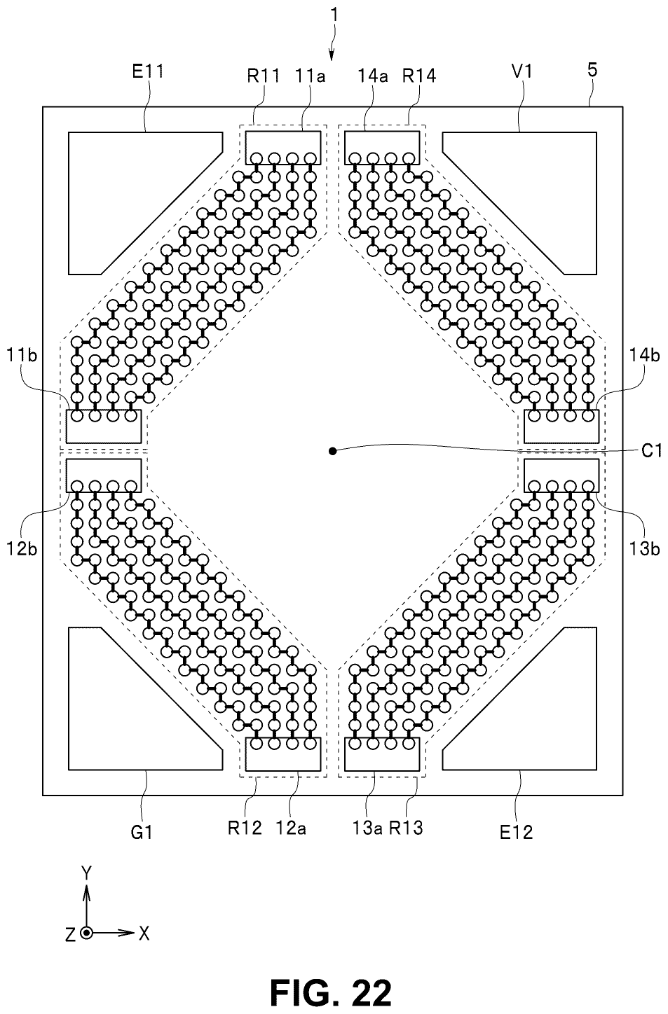

Next, a second example embodiment of the disclosure will be described with reference to FIGS. 20 and 21. FIG. 20 is a circuit diagram showing a circuit configuration of a magnetic sensor according to the example embodiment. FIG. 21 is a plan view showing first and second resistor sections in the example embodiment.

The configuration of a magnetic sensor 1 according to the example embodiment differs from that of the first example embodiment in the following respects. In the example embodiment, the second output terminal E12, the third resistor section R13, and the fourth resistor section R14 in the first example embodiment are not provided.

The first resistor section R11 may include a first auxiliary resistor section R11A and a second auxiliary resistor section R11B disposed at positions different from each other. The second resistor section R12 may include a first auxiliary resistor section R12A and a second auxiliary resistor section R12B disposed at positions different from each other. The first and second auxiliary resistor sections R11A and R11B are provided in this order from the power supply terminal V1 to the first output terminal E11. The first and second auxiliary resistor sections R12A and R12B are provided in this order from the first output terminal E11 to the ground terminal G1.

The configuration and arrangement of the first auxiliary resistor section R11A are similar to those of the first resistor section R11 in the first example embodiment. The configuration and arrangement of the second auxiliary resistor section R11B are similar to those of the third resistor section R13 in the first example embodiment. The first auxiliary resistor section R11A and the second auxiliary resistor section R11B may be in a positional relationship in which, as viewed in the Z direction, the first auxiliary resistor section R11A rotated 180° around the specific point C1 (see FIG. 1) on the substrate 5 overlaps the second auxiliary resistor section R11B.

The configuration and arrangement of the first auxiliary resistor section R12A are similar to those of the second resistor section R12 in the first example embodiment. The configuration and arrangement of the second auxiliary resistor section R12B are similar to those of the fourth resistor section R14 in the first example embodiment. The first and second auxiliary resistor sections R12A and R12B may be in a positional relationship in which, as viewed in the Z direction, the first auxiliary resistor section R12A rotated 180° around the specific point C1 (see FIG. 1) on the substrate 5 overlaps the second auxiliary resistor section R12B.

Hereinafter, a first terminal and a second terminal of the first auxiliary resistor section R11A will be denoted by the reference numerals 11Aa and 11Ab, respectively, and a first terminal and a second terminal of the second auxiliary resistor section R11B will be denoted by the reference numerals 11Ba and 11Bb, respectively. A first terminal and a second terminal of the first auxiliary resistor section R12A will be denoted by the reference numerals 12Aa and 12Ab, respectively, and a first terminal and a second terminal of the second auxiliary resistor section R12B will be denoted by the reference numerals 12Ba and 12Bb, respectively.

The plurality of wiring layers 44 in the example embodiment include a wiring layer 44 connecting the first terminal 11Aa to the power supply terminal V1, a wiring layer 44 connecting the first terminal 12Ba to the ground terminal G1, and a wiring layer 44 connecting the first terminals 11Ba and 12Aa to the first output terminal E11. The plurality of wiring layers 44 further includes a wiring layer 44 connecting the second terminal 11Ab to the second terminal 11Bb, and a wiring layer 44 connecting the second terminal 12Ab to the second terminal 12Bb.

The magnetization 21m of the magnetization pinned layer 21 of each of the plurality of MR elements 20 in the first and second auxiliary resistor sections R11A and R11B includes a component in the first magnetization direction. The magnetization 21m of the magnetization pinned layer 21 of each of the plurality of MR elements 20 in the first and second auxiliary resistor sections R12A and R12B includes a component in the second magnetization direction opposite to the first magnetization direction. In FIG. 20, the two arrows drawn in the vicinity of the first and second auxiliary resistor sections R11A and R11B, respectively, indicate the first magnetization direction. In FIG. 20, the two arrows drawn in the vicinity of the first and second auxiliary resistor sections R12A and R12B, respectively, indicate the second magnetization direction. In particular, in the example embodiment, the first magnetization direction is in the X direction and the second magnetization direction is in the −X direction.

The configuration, operation, and effects of the example embodiment are otherwise the same as those of the first example embodiment.

### Third Example Embodiment

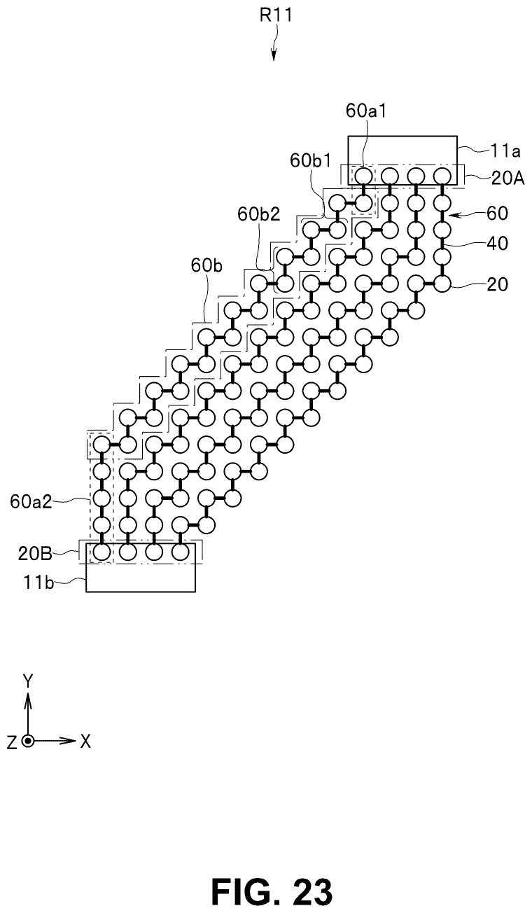

Next, a third example embodiment of the disclosure will be described with reference to FIGS. 22 and 23. FIG. 22 is a plan view showing a magnetic sensor according to the example embodiment. FIG. 23 is a plan view showing a first resistor section according to the example embodiment.

The following describes differences in the configuration of the magnetic sensor 1 according to the example embodiment compared to the first example embodiment, using the first resistor section R11 as an example. In the example embodiment, each of the plurality of element arrays 60 in the first resistor section R11 includes the part 60a1, the part 60b, and the part 60a2 provided in this order from the first terminal 11a side. The part 60a1 includes the first MR element 20A. The part 60a2 includes the second MR element 20B.

The part 60b includes a plurality of parts 60b1 and a plurality of parts 60b2. The part 60b is constituted by the parts 60b1 and 60b2 connected alternately.

Each of the parts 60a1 and 60a2 and the plurality of parts 60b2 extends in the direction parallel to the Y direction. Each of the plurality of parts 60b1 extends in the direction parallel to the X direction. Each of the plurality of element arrays 60 extends from the first terminal 11a to the second terminal 11b, with the respective parts alternately extending in the −Y and −X directions.

In each of the parts 60a1 and 60a2 and the plurality of parts 60b2, the plurality of MR elements 20 are aligned in the direction parallel to the Y direction. In each of the plurality of parts 60b1, the plurality of MR elements 20 are aligned in the direction parallel to the X direction. In the example shown in FIG. 23, in each of the plurality of parts 60b1, two MR elements 20 are aligned in the direction parallel to the X direction. In each of the plurality of parts 60b2, two MR elements 20 are aligned in the direction parallel to the Y direction.

The part 60a1 satisfies the requirement for the number of the MR elements 20 in the first part 60a1 in the first example embodiment. The part 60a2 satisfies the requirement for the number of the MR elements 20 in the third part 60a2 in the first example embodiment. The total number of the MR elements 20 included in the parts 60a1 and 60a2 is the same regardless of the element array 60 to which all the parts 60al and 60a2 belong.

The parts 60b1 and 60b2 each satisfy the requirement for the number of the MR elements 20 in the second part 60b in the first example embodiment. In the example embodiment, the number of the MR elements 20 included in each of the plurality of element arrays 60 is the same regardless of the element array 60.

The above description of the first resistor section R11 also applies to the second through fourth resistor sections R12 to R14. The description of the first terminal, the second terminal, and the plurality of element arrays of each of the first through fourth resistor sections R11 to R14 described in the first example embodiment also applies to the first through fourth resistor sections R11 to R14 in the example embodiment.

### Modification Example

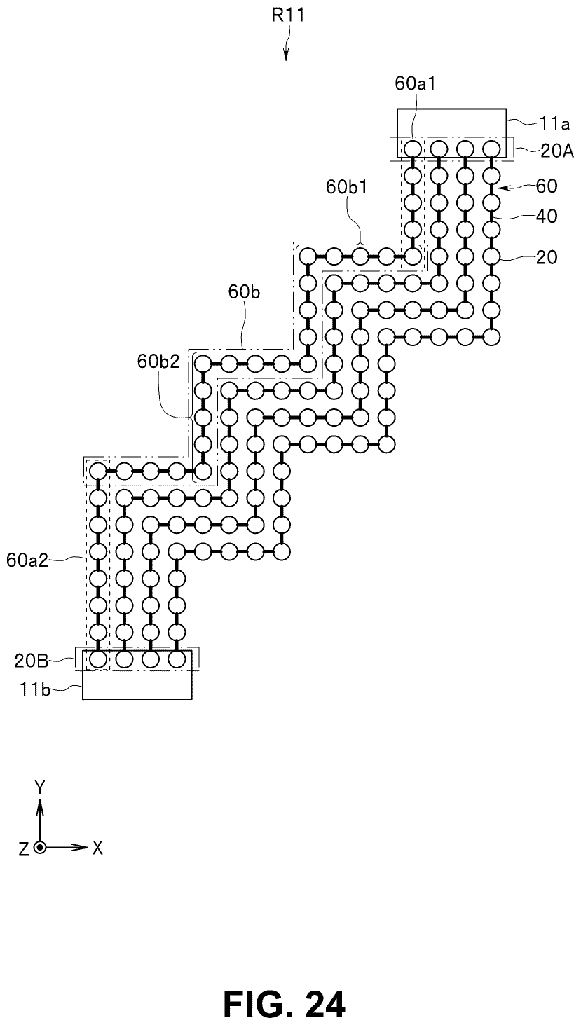

Next, a modification example of the magnetic sensor 1 according to the example embodiment will be described with reference to FIG. 24. FIG. 24 is a plan view showing the first resistor section R11 in the modification example. In the modification example, in each of the plurality of parts 60b1, five MR elements 20 are aligned in the direction parallel to the X direction. In each of the plurality of parts 60b2, five MR elements 20 are aligned in the direction parallel to the Y direction.

The configuration, operation, and effects of the example embodiment are otherwise the same as those of the first example embodiment.

### Forth Example Embodiment

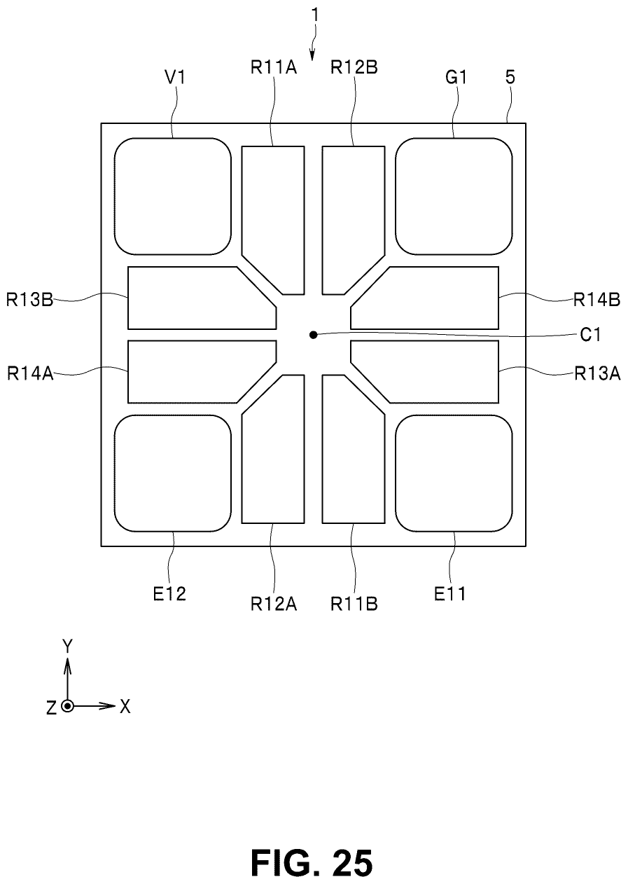

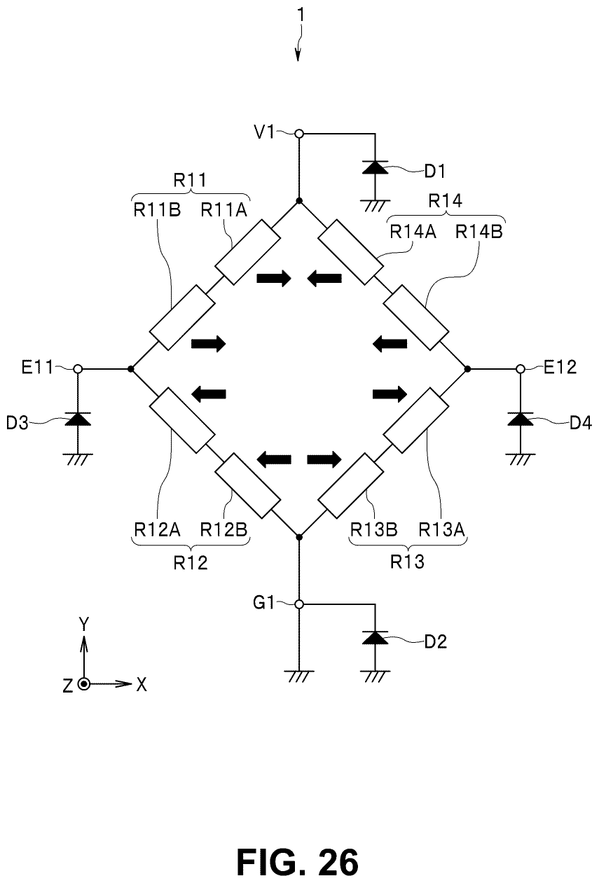

Next, a fourth example embodiment of the disclosure will be described. Initially, a schematic configuration of a magnetic sensor according to the example embodiment will be described with reference to FIGS. 25 and 26. FIG. 25 is a plan view showing the magnetic sensor according to the example embodiment. FIG. 26 is a circuit diagram showing a circuit configuration of the magnetic sensor according to the example embodiment.

The configuration of the magnetic sensor 1 according to the example embodiment differs from that in the first example embodiment in the following respects. The first resistor section R11 includes the first auxiliary resistor section R11A and the second auxiliary resistor section R11B disposed at positions different from each other. The second resistor section R12 includes the first auxiliary resistor section R12A and the second auxiliary resistor section R12B disposed at positions different from each other. The third resistor section R13 includes a first auxiliary resistor section R13A and a second auxiliary resistor section R13B disposed at positions different from each other. The fourth resistor section R14 includes a first auxiliary resistor section R14A and a second auxiliary resistor section R14B disposed at positions different from each other.

The first and second auxiliary resistor sections R11A and R11B are provided in this order from the power supply terminal V1 to the first output terminal E11. The first and second auxiliary resistor sections R12A and R12B are provided in this order from the first output terminal E11 to the ground terminal G1. The first and second auxiliary resistor sections R13A and R13B are provided in this order from the second output terminal E12 to the ground terminal G1. The first and second auxiliary resistor sections R14A and R14B are provided in this order from the power supply terminal V1 to the second output terminal E12.

The first auxiliary resistor section R11A and the second auxiliary resistor section R11B are in a positional relationship in which, as viewed in the Z direction, the first auxiliary resistor section R11A rotated 180° around the specific point C1 on the substrate 5 overlaps the second auxiliary resistor section R11B. The first auxiliary resistor section R12A and the second auxiliary resistor section R12B are in a positional relationship in which, as viewed in the Z direction, the first auxiliary resistor section R12A rotated 180° around the specific point C1 on the substrate 5 overlaps the second auxiliary resistor section R12B. The first auxiliary resistor section R13A and the second auxiliary resistor section R13B are in a positional relationship in which, as viewed in the Z direction, the first auxiliary resistor section R13A rotated 180° around the specific point C1 on the substrate 5 overlaps the second auxiliary resistor section R13B. The first auxiliary resistor section R14A and the second auxiliary resistor section R14B are in a positional relationship in which, as viewed in the Z direction, the first auxiliary resistor section R14A rotated 180° around the specific point C1 on the substrate 5 overlaps the second auxiliary resistor section R14B.

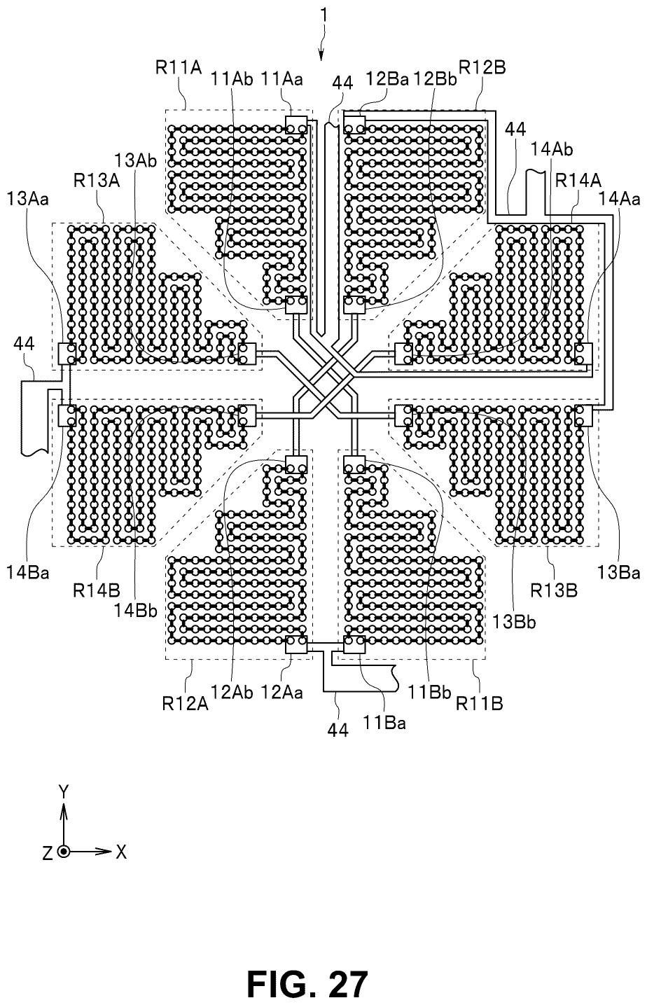

Next, the configuration of the first auxiliary resistor sections R11A, R12A, R13A, and R14A and the second auxiliary resistor sections R11B, R12B, R13B, and R14B will be described with reference to FIG. 27. FIG. 27 is a plan view showing the first auxiliary resistor sections R11A, R12A, R13A, and R14A and the second auxiliary resistor sections R11B, R12B, R13B, and R14B.

Each of the first auxiliary resistor sections R11A, R12A, R13A, and R14A and the second auxiliary resistor sections R11B, R12B, R13B, and R14B includes the first terminal, the second terminal, and the plurality of element arrays 60, similarly to the first through fourth resistor sections R11 to R14 in the first example embodiment. Hereinafter, the first terminal and the second terminal of the first auxiliary resistor section R11A will be denoted by the reference numerals 11Aa and 11Ab, respectively, and the first terminal and the second terminal of the second auxiliary resistor section R11B will be denoted by the reference numerals 11Ba and 11Bb, respectively. The first terminal and the second terminal of the first auxiliary resistor section R12A will be denoted by the reference numerals 12Aa and 12Ab, respectively, and the first terminal and the second terminal of the second auxiliary resistor section R12B will be denoted by the reference numerals 12Ba and 12Bb, respectively. The first terminal and the second terminal of the first auxiliary resistor section R13A will be denoted by the reference numerals 13Aa and 13Ab, respectively, and the first terminal and the second terminal of the second auxiliary resistor section R13B will be denoted by the reference numerals 13Ba and 13Bb, respectively. The first terminal and the second terminal of the first auxiliary resistor section R14A will be denoted by the reference numerals 14Aa and 14Ab, respectively, and the first terminal and the second terminal of the second auxiliary resistor section R14B will be denoted by the reference numerals 14Ba and 14Bb, respectively.

The plurality of wiring layers 44 in the example embodiment include a wiring layer 44 connecting the first terminals 11Aa and 14Aa to the power supply terminal V1, a wiring layer 44 connecting the first terminals 12Ba and 13Ba to the ground terminal G1, a wiring layer 44 connecting the first terminals 11Ba and 12Aa to the first output terminal E11, and a wiring layer 44 connecting the first terminals 13Aa and 14Ba to the second output terminal E12. The plurality of wiring layers 44 further includes a wiring layer 44 connecting the second terminal 11Ab to the second terminal 11Bb, a wiring layer 44 connecting the second terminal 12Ab to the second terminal 12Bb, a wiring layer 44 connecting the second terminal 13Ab to the second terminal 13Bb, and a wiring layer 44 connecting the second terminal 14Ab to the second terminal 14Bb.

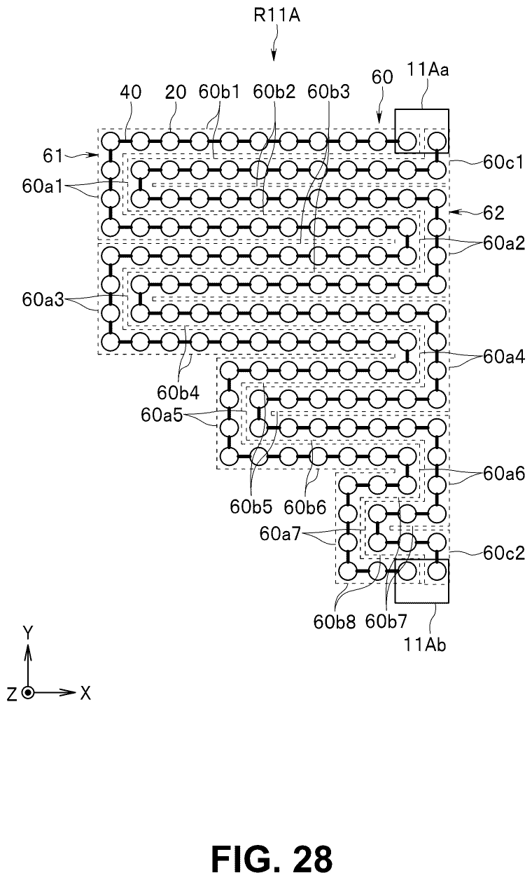

Next, the arrangement of the plurality of MR elements 20 and the configuration of the element array 60 will be described in detail with reference to FIG. 28. FIG. 28 is a plan view showing the first auxiliary resistor section R11A of the first resistor section R11. Here, description will be made by taking the first auxiliary resistor section R11A as an example.

The plurality of element arrays 60 of the first auxiliary resistor section R11A include a first element array 61 and a second element array 62. Each of the first and second element arrays 61 and 62 includes the part 60b1, the part 60a1, the part 60b2, the part 60a2, a part 60b3, the part 60a3, a part 60b4, the part 60a4, a part 60b5, the part 60a5, a part 60b6, a part 60a6, a part 60b7, a part 60a7, and a part 60b8 provided in this order from the first terminal 11Aa side. The second element array 62 further includes the part 60cl provided between the first terminal 11Aa and the part 60b1, and the part 60c2 provided between the second terminal 11Ab and the part 60b8. Each of the part 60b1 of the first element array 61 and the part 60cl of the second element array 62 includes the first MR element 20A. Each of the part 60b8 of the first element array 61 and the part 60c2 of the second element array 62 includes the second MR element 20B.

Each of the parts 60a1 to 60a7, 60cl, and 60c2 extends in the direction parallel to the Y direction. Each of the parts 60b1 to 60b8 extends in the direction parallel to the X direction. Each of the first and second element arrays 61 and 62 extends in a meander shape when viewed in the Z direction.

In each of the parts 60a1 to 60a7, 60cl, and 60c2, the plurality of MR elements 20 are aligned in the direction parallel to the Y direction. In each of the parts 60b1 to 60b8, the plurality of MR elements 20 are aligned in the direction parallel to the X direction.

The parts 60a1 to 60a7 each satisfy the requirement for the number of the MR elements 20 in the first part 60a1 or the third part 60a2 in the first example embodiment. The parts 60b1 to 60b8 each satisfy the requirement for the number of the MR elements 20 in the second part 60b, described with reference to FIG. 4. The number of the MR elements 20 in the first element array 61 and the number of the MR elements 20 in the second element array 62 are the same.

Heretofore, description has been made by taking the first auxiliary resistor section R11A as an example. The above description of the first auxiliary resistor section R11A also applies to the first auxiliary resistor sections R12A, R13A, and R14A and the second auxiliary resistor sections R11B, R12B, R13B, and R14B.

Note that, as shown in FIG. 27, the first terminal 12Aa, the second terminal 12Ab, and the plurality of element arrays 60 of the first auxiliary resistor section R12A may be symmetrical about the XZ plane with respect to the first terminal 11Aa, the second terminal 11Ab, and the plurality of element arrays 60 of the first auxiliary resistor section R11A. The first terminal 12Ba, the second terminal 12Bb, and the plurality of element arrays 60 of the second auxiliary resistor section R12B may be symmetrical about the YZ plane with respect to the first terminal 11Aa, the second terminal 11Ab, and the plurality of element arrays 60 of the first auxiliary resistor section R11A.

The first auxiliary resistor section R12A and the second auxiliary resistor section R13B may be in a positional relationship in which, as viewed in the Z direction, the first auxiliary resistor section R12A rotated 90° around the specific point C1 overlaps the second auxiliary resistor section R13B. The second auxiliary resistor section R12B and the first auxiliary resistor section R13A may be in a positional relationship in which, as viewed in the Z direction, the second auxiliary resistor section R12B rotated 90° around the specific point C1 overlaps the first auxiliary resistor section R13A.

The first terminal 14Aa, the second terminal 14Ab, and the plurality of element arrays 60 of the first auxiliary resistor section R14A may be symmetrical about the XZ plane with respect to the first terminal 13Ba, the second terminal 13Bb, and the plurality of element arrays 60 of the second auxiliary resistor section R13B. The first terminal 14Ba, the second terminal 14Bb, and the plurality of element arrays 60 of the second auxiliary resistor section R14B may be symmetrical about the XZ plane with respect to the first terminal 13Aa, the second terminal 13Ab, and the plurality of element arrays 60 of the first auxiliary resistor section R13A.

Next, with reference to FIG. 26, the direction of the magnetization 21m of the magnetization pinned layer 21 in each of the first auxiliary resistor sections R11A, R12A, R13A, and R14A and the second auxiliary resistor sections R11B, R12B, R13B, and R14B will be described. The magnetization 21m of the magnetization pinned layer 21 of each of the plurality of MR elements 20 in the first auxiliary resistor sections R11A and R13A and the second auxiliary resistor sections R11B and R13B includes a component in the first magnetization direction. The magnetization 21m of the magnetization pinned layer 21 of each of the plurality of MR elements 20 in the first auxiliary resistor sections R12A and R14A and the second auxiliary resistor sections R12B and R14B includes a component in the second magnetization direction opposite to the first magnetization direction. In FIG. 26, the four arrows drawn in the vicinity of the first auxiliary resistor sections R11A and R13A and the second auxiliary resistor sections R11B and R13B, respectively, indicate the first magnetization direction. In FIG. 26, the four arrows drawn in the vicinity of the first auxiliary resistor sections R12A and R14A and the second auxiliary resistor sections R12B and R14B, respectively, indicate the second magnetization direction. In particular, in the example embodiment, the first magnetization direction is in the X direction and the second magnetization direction is in the −X direction.

The configuration, operation, and effects of the example embodiment are otherwise the same as those of the first example embodiment.

### Fifth Example Embodiment

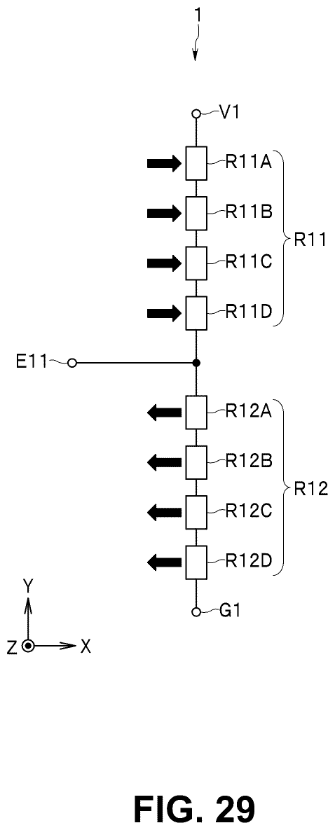

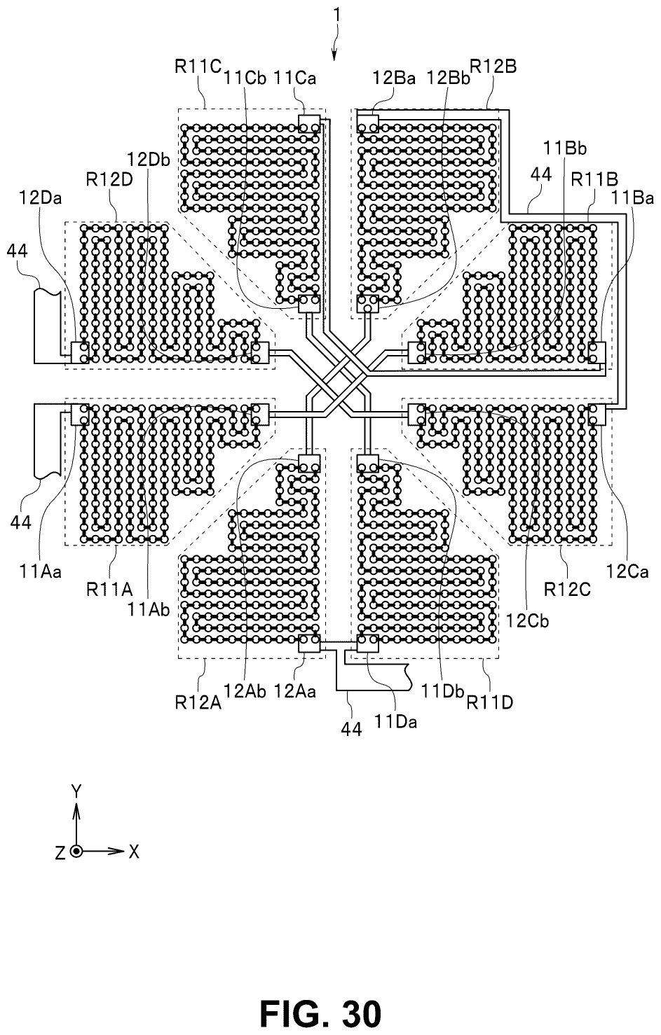

Next, a fifth example embodiment of the disclosure will be described with reference to FIGS. 29 and 30. FIG. 29 is a circuit diagram showing a circuit configuration of a magnetic sensor according to the example embodiment. FIG. 30 is a plan view showing first and second resistor sections in the example embodiment.

The configuration of the magnetic sensor 1 according to the example embodiment differs from that of the fourth example embodiment in the following respects. In the example embodiment, the second output terminal E12, the third resistor section R13, and the fourth resistor section R14 in the fourth example embodiment are not provided.

The first resistor section R11 includes the first and second auxiliary resistor sections R11A and R11B, as well as a third auxiliary resistor section R11C and a fourth auxiliary resistor section R11D. The first through fourth auxiliary resistor sections R11A, R11B, R11C, and R11D are disposed at positions different from each other. The first through fourth auxiliary resistor sections R11A, R11B, R11C, and R11D are provided in this order from the power supply terminal V1 to the first output terminal E11.

The second resistor section R12 includes the first and second auxiliary resistor sections R12A and R12B, as well as a third auxiliary resistor section R12C and a fourth auxiliary resistor section R12D. The first through fourth auxiliary resistor sections R12A, R12B, R12C, and R12D are disposed at positions different from each other. The first through fourth auxiliary resistor sections R12A, R12B, R12C, and R12D are provided in this order from the first output terminal E11 to the ground terminal G1.

The configuration and arrangement of the first auxiliary resistor section R11A are similar to those of the second auxiliary resistor section R14B in the fourth example embodiment. The configuration and arrangement of the second auxiliary resistor section R11B are similar to those of the first auxiliary resistor section R14A in the fourth example embodiment. The configuration and arrangement of the third auxiliary resistor section R11C are similar to those of the first auxiliary resistor section R11A in the fourth example embodiment. The configuration and arrangement of the fourth auxiliary resistor section R11D are similar to those of the second auxiliary resistor section R11B in the fourth example embodiment.

The configuration and arrangement of the first auxiliary resistor section R12A are similar to those of the first auxiliary resistor section R12A in the fourth example embodiment. The configuration and arrangement of the second auxiliary resistor section R12B are similar to those of the second auxiliary resistor section R12B in the fourth example embodiment. The configuration and arrangement of the third auxiliary resistor section R12C are similar to those of the second auxiliary resistor section R13B in the fourth example embodiment. The configuration and arrangement of the fourth auxiliary resistor section R12D are similar to those of the first auxiliary resistor section R13A in the fourth example embodiment.

Hereinafter, the first terminal and the second terminal of the third auxiliary resistor section R11C will be denoted by the reference numerals 11Ca and 11Cb, respectively, and the first terminal and the second terminal of the fourth auxiliary resistor section R11D will be denoted by the reference numerals 11Da and 11Db, respectively. The first terminal and the second terminal of the third auxiliary resistor section R12C will be denoted by the reference numerals 12Ca and 12Cb, respectively, and the first terminal and the second terminal of the fourth auxiliary resistor section R12D will be denoted by the reference numerals 12Da and 12Db, respectively.

The plurality of wiring layers 44 in the example embodiment includes a wiring layer 44 connecting the first terminal 11Aa to the power supply terminal V1, a wiring layer 44 connecting the second terminal 12Da to the ground terminal G1, and a wiring layer 44 connecting the first terminals 11Da and 12Aa to the first output terminal E11. The plurality of wiring layers 44 further includes a wiring layer 44 connecting the second terminal 11Ab to the second terminal 11Bb, a wiring layer 44 connecting the first terminal 11Ba to the first terminal 11Ca, a wiring layer 44 connecting the second terminal 11Cb to the second terminal 11Db, a wiring layer 44 connecting the second terminal 12Ab to the second terminal 12Bb, a wiring layer 44 connecting the first terminal 12Ba to the first terminal 12Ca, and a wiring layer 44 connecting the second terminal 12Cb to the second terminal 12Db.

The magnetization 21m of the magnetization pinned layer 21 of each of the plurality of MR elements 20 in the first through fourth auxiliary resistor sections R11A, R11B, R11C, and R11D includes a component in the first magnetization direction. The magnetization 21m of the magnetization pinned layer 21 of each of the plurality of MR elements 20 in the first through fourth auxiliary resistor sections R12A, R12B, R12C, and R12D includes a component in the second magnetization direction opposite to the first magnetization direction. In FIG. 29, the four arrows drawn in the vicinity of the first through fourth auxiliary resistor sections R11A, R11B, R11C, and R11D, respectively, indicate the first magnetization direction. In FIG. 29, the four arrows drawn in the vicinity of the first through fourth auxiliary resistor sections R12A, R12B, R12C, and R12D, respectively, indicate the second magnetization direction. In particular, in the example embodiment, the first magnetization direction is in the X direction and the second magnetization direction is in the −X direction.

The configuration, operation, and effects of the example embodiment are otherwise the same as those of the first example embodiment.

### Sixth Example Embodiment

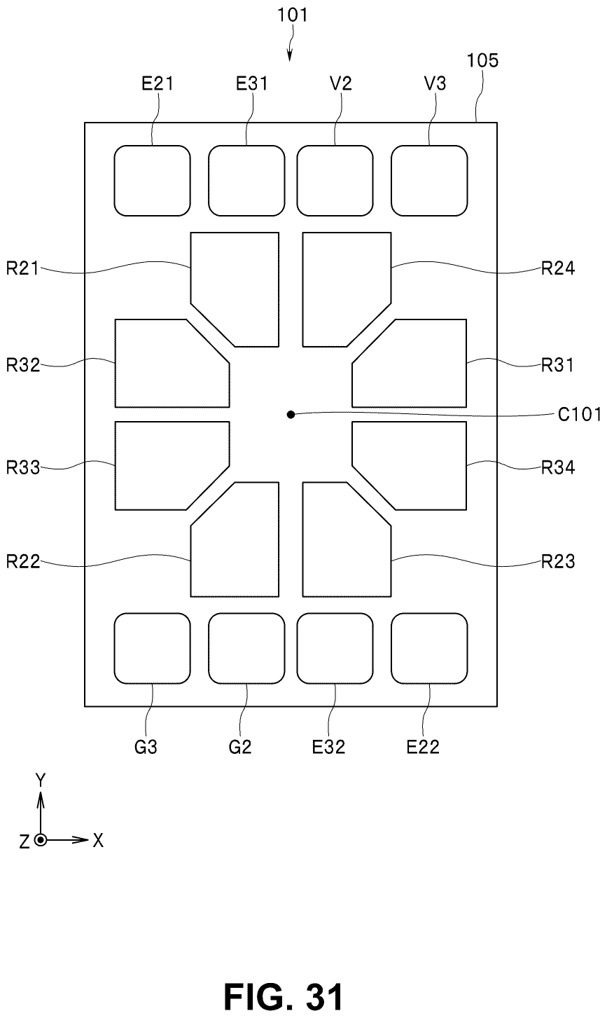

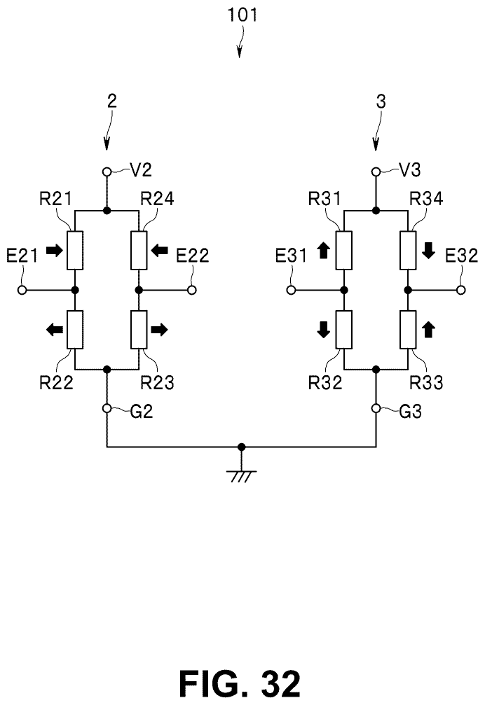

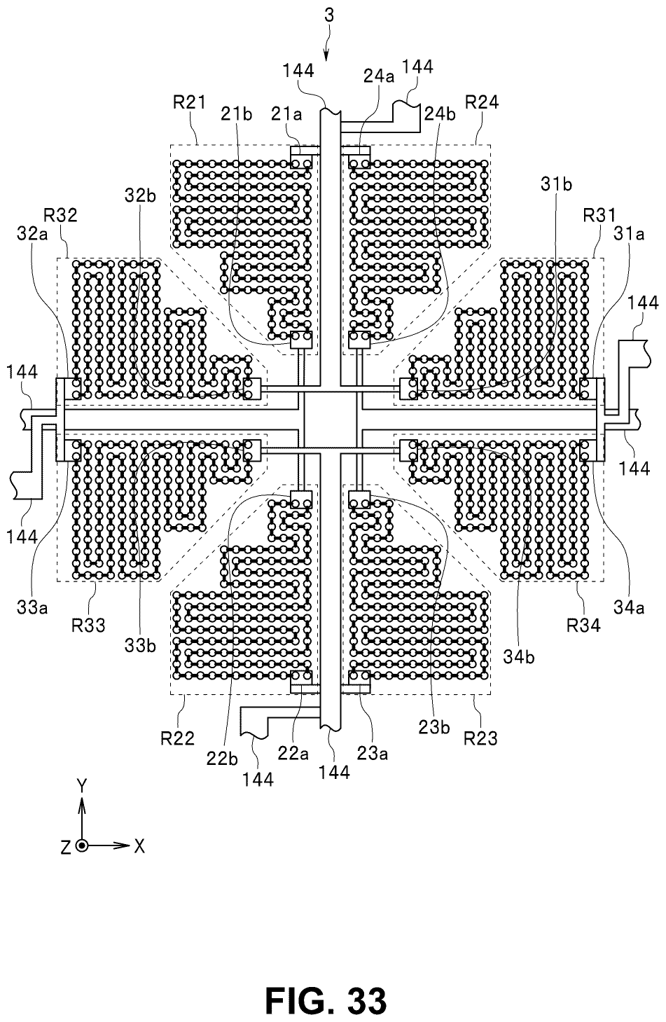

Next, a sixth example embodiment of the disclosure will be described with reference to FIGS. 31 through 33. FIG. 31 is a plan view showing a magnetic sensor according to the example embodiment. FIG. 32 is a circuit diagram showing a circuit configuration of the magnetic sensor according to the example embodiment. FIG. 33 is a plan view showing first through eighth resistor sections in the example embodiment.

A magnetic sensor 101 according to the example embodiment includes a first detection circuit 2 and a second detection circuit 3. The configuration of each of the first and second detection circuits 2 and 3 is basically the same as that of the magnetic sensor 1 according to the first example embodiment. In other words, each of the first and second detection circuits 2 and 3 includes the plurality of MR elements 20.

The first detection circuit 2 further includes a power supply terminal V2, a ground terminal G2, a first output terminal E21, a second output terminal E22, a first resistor section R21, a second resistor section R22, a third resistor section R23, and a fourth resistor section R24. The power supply terminal V2, the ground terminal G2, the first output terminal E21, and the second output terminal E22 are each constituted of an electrode layer formed of a conductive material. Each of the first through fourth resistor sections R21 to R24 includes multiple MR elements 20 among the plurality of MR elements 20.

As shown in FIG. 32, the first resistor section R21 is provided between the power supply terminal V2 and the first output terminal E21 in the circuit configuration. The second resistor section R22 is provided between the ground terminal G2 and the first output terminal E21 in the circuit configuration. The third resistor section R23 is provided between the ground terminal G2 and the second output terminal E22 in the circuit configuration. The fourth resistor section R24 is provided between the power supply terminal V2 and the second output terminal E22 in the circuit configuration.

A voltage or current of a specific magnitude is applied to the power supply terminal V2. The ground terminal G2 is connected to the ground.

The first detection circuit 2 may further include four diodes (not shown). The connection relationship between the four diodes and the power supply terminal V2, the ground terminal G2, the first output terminal E21, and the second output terminal E22 is similar to the connection relationship between the four diodes D1 to D4 and the power supply terminal V1, the ground terminal G1, the first output terminal E11, and the second output terminal E12 in the first example embodiment.

The second detection circuit 3 further includes a power supply terminal V3, a ground terminal G3, a first output terminal E31, a second output terminal E32, a fifth resistor section R31, a sixth resistor section R32, a seventh resistor section R33, and an eighth resistor section R34. The power supply terminal V3, the ground terminal G3, the first output terminal E31, and the second output terminal E32 are each constituted of an electrode layer formed of a conductive material. Each of the fifth through eighth resistor sections R31 to R34 includes multiple MR elements 20 among the plurality of MR elements 20.

As shown in FIG. 32, the fifth resistor section R31 is provided between the power supply terminal V3 and the first output terminal E31 in the circuit configuration. The sixth resistor section R32 is provided between the ground terminal G3 and the first output terminal E31 in the circuit configuration. The seventh resistor section R33 is provided between the ground terminal G3 and the second output terminal E32 in the circuit configuration. The eighth resistor section R34 is provided between the power supply terminal V3 and the second output terminal E32 in the circuit configuration.

A voltage or current of a specific magnitude is applied to the power supply terminal V3. The ground terminal G3 is connected to the ground.

The second detection circuit 3 may further include four diodes (not shown). The connection relationship between the four diodes and the power supply terminal V3, the ground terminal G3, the first output terminal E31, and the second output terminal E32 is similar to the connection relationship between the four diodes D1 to D4 and the power supply terminal V1, the ground terminal G1, the first output terminal E11, and the second output terminal E12 in the first example embodiment.

The magnetic sensor 101 further includes a substrate 105. The power supply terminals V2 and V3, the ground terminals G2 and G3, the first output terminals E21 and E31, the second output terminals E22 and E32, and the first through eighth resistor sections R21 to R24 and R31 to R34 are provided on the substrate 105.

FIG. 31 shows an example of an arrangement of the first through eighth resistor sections R21 to R24 and R31 to R34. The first resistor section R21 and the third resistor section R23 are in a positional relationship in which, as viewed in the Z direction, the first resistor section R21 rotated 180° around a specific point C101 on the substrate 105 overlaps the third resistor section R23. The second resistor section R22 and the fourth resistor section R24 are in a positional relationship in which, as viewed in the Z direction, the second resistor section R22 rotated 180° around the specific point C101 overlaps the fourth resistor section R24. The specific point C101 may be the center of gravity of the surface of the substrate 105 when viewed in the Z direction.

The second resistor section R22 is disposed symmetrically with respect to the first resistor section R21 about the XZ plane including the specific point C101. The fourth resistor section R24 is disposed symmetrically with respect to the third resistor section R23 about the XZ plane including the specific point C101.

The fifth resistor section R31 and the seventh resistor section R33 are in a positional relationship in which, as viewed in the Z direction, the fifth resistor section R31 rotated 180° around the specific point C101 on the substrate 105 overlaps the seventh resistor section R33. The sixth resistor section R32 and the eighth resistor section R34 are in a positional relationship in which, as viewed in the Z direction, the sixth resistor section R32 rotated 180° around the specific point C101 overlaps the eighth resistor section R34.

The sixth resistor section R32 is disposed symmetrically with respect to the fifth resistor section R31 about the YZ plane including the specific point C101. The eighth resistor section R34 is disposed symmetrically with respect to the seventh resistor section R33 about the YZ plane including the specific point C101.

Each of the first through eighth resistor sections R21 to R24 and R31 to R34 includes the plurality of element arrays 60, the first terminal, and the second terminal, similarly to the first through fourth resistor sections R11 to R14 in the first example embodiment. Hereinafter, the first terminal and the second terminal of the first resistor section R21 will be denoted by the reference numerals 21a and 21b, respectively; the first terminal and the second terminal of the second resistor section R22 will be denoted by the reference numerals 22a and 22b, respectively; the first terminal and the second terminal of the third resistor section R23 will be denoted by the reference numerals 23a and 23b, respectively; and the first terminal and the second terminal of the fourth resistor section R24 will be denoted by the reference numerals 24a and 24b, respectively. The first terminal and the second terminal of the fifth resistor section R31 will be denoted by the reference numerals 31a and 31b, respectively; the first terminal and the second terminal of the sixth resistor section R32 will be denoted by the reference numerals 32a and 32b, respectively; the first terminal and the second terminal of the seventh resistor section R33 will be denoted by the reference numerals 33a and 33b, respectively; and the first terminal and the second terminal of the eighth resistor section R34 will be denoted by the reference numerals 34a and 34b, respectively.

The magnetic sensor 101 further includes a plurality of wiring layers 144, each formed of a conductive material. The plurality of wiring layers 144 include a wiring layer 144 connecting the first terminals 21a and 24a to the power supply terminal V2, a wiring layer 144 connecting the first terminals 22a and 23a to the ground terminal G2, a wiring layer 144 connecting the second terminals 21b and 22b to the first output terminal E21, and a wiring layer 144 connecting the second terminals 23b and 24b to the second output terminal E22. The plurality of wiring layers 144 further includes a wiring layer 144 connecting the first terminals 31a and 34a to the power supply terminal V3, a wiring layer 144 connecting the first terminals 32a and 33a to the ground terminal G3, a wiring layer 144 connecting the second terminals 31b and 32b to the first output terminal E31, and a wiring layer 144 connecting the second terminals 33b and 34b to the second output terminal E32.

The specific configuration and arrangement of the first resistor section R21 are similar to those of the first auxiliary resistor section R11A in the fourth example embodiment. The specific configuration and arrangement of the second resistor section R22 are similar to those of the first auxiliary resistor section R12A in the fourth example embodiment. The specific configuration and arrangement of the third resistor section R23 are similar to those of the second auxiliary resistor section R11B in the fourth example embodiment. The specific configuration and arrangement of the fourth resistor section R24 are similar to those of the second auxiliary resistor section R12B in the fourth example embodiment.

The specific configuration and arrangement of the fifth resistor section R31 are similar to those of the first auxiliary resistor section R14A in the fourth example embodiment. The specific configuration and arrangement of the sixth resistor section R32 are similar to those of the first auxiliary resistor section R13A in the fourth example embodiment. The specific configuration and arrangement of the seventh resistor section R33 are similar to those of the second auxiliary resistor section R14B in the fourth example embodiment. The specific configuration and arrangement of the eighth resistor section R34 are similar to those of the second auxiliary resistor section R13B in the fourth example embodiment.

The configuration, operation, and effects of the example embodiment are otherwise the same as those of the first or fourth example embodiment.

### Seventh Example Embodiment

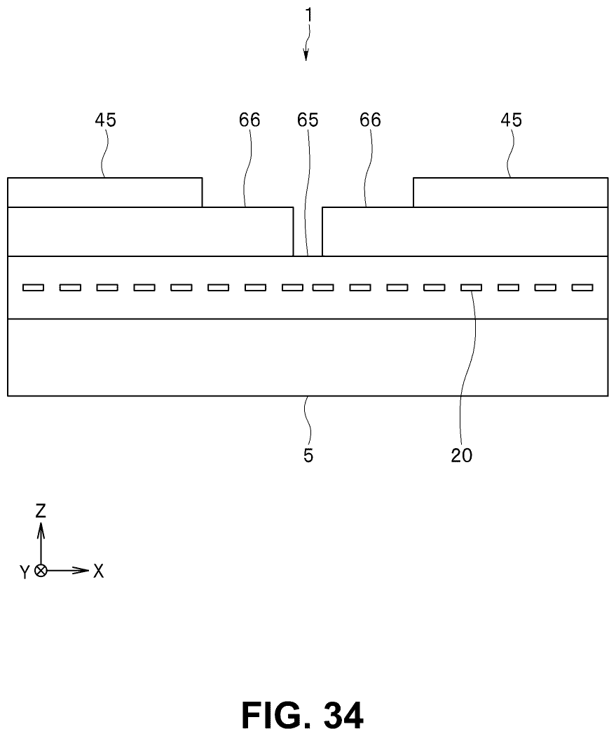

Next, a seventh example embodiment of the disclosure will be described with reference to FIG. 34. FIG. 34 is a cross-sectional view showing a magnetic sensor according to the example embodiment.

The configuration of the magnetic sensor 1 according to the example embodiment differs from that in the first example embodiment in the following respects. In the example embodiment, at least one of the power supply terminal V1, the ground terminal G1, the first output terminal E11, and the second output terminal E12 is disposed so as to overlap a portion of the plurality of MR elements 20 as viewed in the Z direction. In FIG. 34, the reference numeral 45 indicates the electrode layer constituting any of the power supply terminal V1, the ground terminal G1, the first output terminal E11, and the second output terminal E12.

The magnetic sensor 1 further includes an insulating layer 65 disposed around the plurality of MR elements 20 on the substrate 5, and an intermediate layer 66 provided between the insulating layer 65 and the electrode layer 45. The intermediate layer 66 is formed, for example, of an insulating material having a Poisson's ratio larger than that of the insulating material forming the insulating layer 65.

To make a comparison using the same planar shape of the magnetic sensor 1, according to the example embodiment, it is possible to increase the number of the MR elements 20 than the case where the electrode layer 45 does not overlap a portion of the plurality of MR elements 20.

The configuration, operation, and effects of the example embodiment are otherwise the same as those of the first example embodiment.

Note that the disclosure is not limited to each of the foregoing example embodiments, and various modifications may be made thereto. For example, the number of the plurality of MR elements 20, the number of the multiple MR elements 20 included in the plurality of element arrays 60, and the shape of the plurality of element arrays 60 are not limited to the examples shown in each example embodiment, but are arbitrary, as long as the requirements of the claims are met.

In the fourth modification example of the first example embodiment, either the plurality of first MR elements 20A or the plurality of second MR elements 20B may be aligned in the direction parallel to the X direction, and the other in the direction parallel to the Y direction. In this case, either the plurality of MR elements 20 in the part 60A connected to the third terminal 11c or the plurality of MR elements 20 in the part 60B connected to the third terminal 11c may be aligned in the direction parallel to the X direction, and the other in the direction parallel to the Y direction.

As described above, a magnetic sensor according to one embodiment of the disclosure includes: a plurality of magnetoresistive elements; a plurality of element arrays each including a wiring and multiple elements, the multiple elements being among the plurality of magnetoresistive elements and connected in series by the wiring; a first terminal; and a second terminal. The plurality of element arrays are connected in parallel with each other by the first terminal and the second terminal. Of the plurality of magnetoresistive elements, multiple elements are arrayed both in a first direction and a second direction that intersects the first direction. Each of the plurality of element arrays includes a first part, a second part, and a third part that are provided in this order from a side of the first terminal. Each of the first part and the third part extends in the first direction. The second part extends in the second direction. Among the multiple elements, the number of elements included in the first part differs depending on an element array to which the first part belongs among the plurality of element arrays. Among the multiple elements, the number of elements included in the second part is the same regardless of an element array to which the second part belongs among the plurality of element arrays. Among the multiple elements, the number of elements included in the third part differs depending on an element array to which the third part belongs among the plurality of element arrays.

In the magnetic sensor according to one embodiment of the disclosure, the plurality of magnetoresistive elements may include a plurality of first elements connected to the first terminal and a plurality of second elements connected to the second terminal. The plurality of first elements may be aligned in a row along the first direction or the second direction. The plurality of second elements may be aligned in a row along the first direction or the second direction. The plurality of first elements and the plurality of second elements may be aligned in the same direction.

In the magnetic sensor according to one embodiment of the disclosure, among the multiple elements, a sum of the number of elements included in the first part and the number of elements included in the third part may be the same regardless of an element array to which both the first part and the third part belong among the plurality of element arrays.

The magnetic sensor according to one embodiment of the disclosure may further include a third terminal. The plurality of element arrays may include a part where the plurality of element arrays are connected in parallel by the first terminal and the third terminal, and a part where the plurality of element arrays are connected in parallel by the second terminal and the third terminal.

In the magnetic sensor according to one embodiment of the disclosure, each of the plurality of magnetoresistive elements may include a magnetization pinned layer having a magnetization whose direction is fixed, and a free layer having a magnetization that is variable in response to a magnetic field applied thereto. The free layer may have a magnetic vortex structure, and may be configured such that a center of the magnetic vortex structure moves in response to a target magnetic field. The magnetic sensor according to one embodiment of the disclosure may further include a first resistor section, and a second resistor section connected to the first resistor section. Each of the first resistor section and the second resistor section may include the plurality of magnetoresistive elements, the plurality of element arrays, the first terminal, and the second terminal. The magnetization of the magnetization pinned layer of each of the plurality of magnetoresistive elements of the first resistor section may include a component in a first magnetization direction. The magnetization of the magnetization pinned layer of each of the plurality of magnetoresistive elements of the second resistor section may include a component in a second magnetization direction opposite to the first magnetization direction.

The magnetic sensor according to one embodiment of the disclosure may further include a power supply terminal, a ground terminal, a first output terminal, a second output terminal, a first resistor section provided between the power supply terminal and the first output terminal, a second resistor section provided between the ground terminal and the first output terminal, a third resistor section provided between the ground terminal and the second output terminal, and a fourth resistor section provided between the power supply terminal and the second output terminal. Each of the first resistor section, the second resistor section, the third resistor section, and the fourth resistor section may include the plurality of magnetoresistive elements, the plurality of element arrays, the first terminal, and the second terminal. The first resistor section and the third resistor section may be in a positional relationship in which, as viewed in a third direction orthogonal to each of the first direction and the second direction, the first resistor section rotated 180° around a specific point overlaps the third resistor section. The second resistor section and the fourth resistor section may be in a positional relationship in which, as viewed in the third direction, the second resistor section rotated 180° around the specific point overlaps the fourth resistor section.

The magnetic sensor according to one embodiment of the disclosure may further include a power supply terminal, a ground terminal, an output terminal, a first resistor section provided between the power supply terminal and the output terminal, and a second resistor section provided between the ground terminal and the output terminal. Each of the first resistor section and the second resistor section may include a first auxiliary resistor section and a second auxiliary resistor section disposed at positions different from each other. Each of the first auxiliary resistor section of the first resistor section, the second auxiliary resistor section of the first resistor section, the first auxiliary resistor section of the second resistor section, and the second auxiliary resistor section of the second resistor section may include the plurality of magnetoresistive elements, the plurality of element arrays, the first terminal, and the second terminal. In each of the first resistor section and the second resistor section, the first auxiliary resistor section and the second auxiliary resistor section may be in a positional relationship in which, as viewed in a third direction orthogonal to each of the first direction and the second direction, the first auxiliary resistor section rotated 180° around a specific point overlaps the second auxiliary resistor section.

The magnetic sensor according to one embodiment of the disclosure may further include a plurality of lower electrodes and a plurality of upper electrodes, each formed of a conductive material. The plurality of magnetoresistive elements may be disposed on the plurality of lower electrodes. The plurality of upper electrodes may be disposed with a spacing from the plurality of magnetoresistive elements in a third direction orthogonal to each of the first direction and the second direction. The plurality of magnetoresistive elements may include a plurality of first-type elements electrically connected to the plurality of upper electrodes, and a plurality of second-type elements not electrically connected to the plurality of upper electrodes. The magnetic sensor according to one embodiment of the disclosure may further include a wiring layer formed of a conductive material, and disposed with a spacing from the plurality of magnetoresistive elements in the third direction. The wiring layer may overlap a portion of the plurality of second-type elements as viewed in the third direction.

The magnetic sensor according to one embodiment of the disclosure may further include an electrode layer formed of a conductive material. The plurality of magnetoresistive elements may include a plurality of specific elements electrically connected to the electrode layer. Of the plurality of specific elements, multiple elements may be arrayed both in the first direction and the second direction. The magnetic sensor according to one embodiment of the disclosure may further include a plurality of via electrodes each formed of a conductive material. The plurality of specific elements may be connected to the electrode layer via the plurality of via electrodes.

In the magnetic sensor of the disclosure, the number of elements included in the first part differs depending on an element array to which the first part belongs, the number of elements included in the second part is the same regardless of an element array to which the second part belongs, and the number of elements included in the third part differs depending on an element array to which the third part belongs. According to the disclosure, this allows increasing the number of magnetoresistive elements while suppressing the degradation of high-frequency noise characteristics and suppressing the size increase of the magnetic sensor.

It is apparent that the disclosure can be carried out in various forms and modification examples in the light of the foregoing descriptions. Accordingly, within the scope of the following claims and equivalents thereof, the disclosure can be carried out in forms other than the foregoing example embodiments.

1. A magnetic sensor comprising:
a plurality of magnetoresistive elements;
a plurality of element arrays each including a wiring and multiple elements, the multiple elements being among the plurality of magnetoresistive elements and connected in series by the wiring;
a first terminal; and
a second terminal, wherein
the plurality of element arrays are connected in parallel with each other by the first terminal and the second terminal,
of the plurality of magnetoresistive elements, multiple elements are arrayed both in a first direction and a second direction that intersects the first direction,
each of the plurality of element arrays includes a first part, a second part, and a third part that are provided in this order from a side of the first terminal,
each of the first part and the third part extends in the first direction,
the second part extends in the second direction,
among the multiple elements, the number of elements included in the first part differs depending on an element array to which the first part belongs among the plurality of element arrays,
among the multiple elements, the number of elements included in the second part is the same regardless of an element array to which the second part belongs among the plurality of element arrays, and
among the multiple elements, the number of elements included in the third part differs depending on an element array to which the third part belongs among the plurality of element arrays.

2. The magnetic sensor according to claim 1, wherein
the plurality of magnetoresistive elements include a plurality of first elements connected to the first terminal and a plurality of second elements connected to the second terminal,
the plurality of first elements are aligned in a row along the first direction or the second direction, and
the plurality of second elements are aligned in a row along the first direction or the second direction.

3. The magnetic sensor according to claim 2, wherein the plurality of first elements and the plurality of second elements are aligned in the same direction.

4. The magnetic sensor according to claim 1, wherein among the multiple elements, a sum of the number of elements included in the first part and the number of elements included in the third part is the same regardless of an element array to which both the first part and the third part belong among the plurality of element arrays.

5. The magnetic sensor according to claim 1, further comprising:
a third terminal, wherein
the plurality of element arrays include a part where the plurality of element arrays are connected in parallel by the first terminal and the third terminal, and a part where the plurality of element arrays are connected in parallel by the second terminal and the third terminal.

6. The magnetic sensor according to claim 1, wherein each of the plurality of magnetoresistive elements includes a magnetization pinned layer having a magnetization whose direction is fixed, and a free layer having a magnetization that is variable in response to a magnetic field applied thereto.

7. The magnetic sensor according to claim 6, wherein the free layer has a magnetic vortex structure, and is configured such that a center of the magnetic vortex structure moves in response to a target magnetic field.

8. The magnetic sensor according to claim 6, further comprising:
a first resistor section; and
a second resistor section connected to the first resistor section, wherein
each of the first resistor section and the second resistor section includes the plurality of magnetoresistive elements, the plurality of element arrays, the first terminal, and the second terminal,
the magnetization of the magnetization pinned layer of each of the plurality of magnetoresistive elements of the first resistor section includes a component in a first magnetization direction, and
the magnetization of the magnetization pinned layer of each of the plurality of magnetoresistive elements of the second resistor section includes a component in a second magnetization direction opposite to the first magnetization direction.

9. The magnetic sensor according to claim 1, further comprising:
a power supply terminal;
a ground terminal;
a first output terminal;
a second output terminal;
a first resistor section provided between the power supply terminal and the first output terminal;
a second resistor section provided between the ground terminal and the first output terminal;
a third resistor section provided between the ground terminal and the second output terminal; and
a fourth resistor section provided between the power supply terminal and the second output terminal, wherein
each of the first resistor section, the second resistor section, the third resistor section, and the fourth resistor section includes the plurality of magnetoresistive elements, the plurality of element arrays, the first terminal, and the second terminal,
the first resistor section and the third resistor section are in a positional relationship in which, as viewed in a third direction orthogonal to each of the first direction and the second direction, the first resistor section rotated 180° around a specific point overlaps the third resistor section, and
the second resistor section and the fourth resistor section are in a positional relationship in which, as viewed in the third direction, the second resistor section rotated 180° around the specific point overlaps the fourth resistor section.

10. The magnetic sensor according to claim 1, further comprising:
a power supply terminal;
a ground terminal;
an output terminal;
a first resistor section provided between the power supply terminal and the output terminal; and
a second resistor section provided between the ground terminal and the output terminal, wherein
each of the first resistor section and the second resistor section includes a first auxiliary resistor section and a second auxiliary resistor section disposed at positions different from each other,
each of the first auxiliary resistor section of the first resistor section, the second auxiliary resistor section of the first resistor section, the first auxiliary resistor section of the second resistor section, and the second auxiliary resistor section of the second resistor section includes the plurality of magnetoresistive elements, the plurality of element arrays, the first terminal, and the second terminal, and
in each of the first resistor section and the second resistor section, the first auxiliary resistor section and the second auxiliary resistor section are in a positional relationship in which, as viewed in a third direction orthogonal to each of the first direction and the second direction, the first auxiliary resistor section rotated 180° around a specific point overlaps the second auxiliary resistor section.

11. The magnetic sensor according to claim 1, further comprising:
a plurality of lower electrodes and a plurality of upper electrodes, each formed of a conductive material, wherein
the plurality of magnetoresistive elements are disposed on the plurality of lower electrodes,
the plurality of upper electrodes are disposed with a spacing from the plurality of magnetoresistive elements in a third direction orthogonal to each of the first direction and the second direction, and
the plurality of magnetoresistive elements include a plurality of first-type elements electrically connected to the plurality of upper electrodes, and a plurality of second-type elements not electrically connected to the plurality of upper electrodes.

12. The magnetic sensor according to claim 11, further comprising:
a wiring layer formed of a conductive material, and disposed with a spacing from the plurality of magnetoresistive elements in the third direction, wherein
the wiring layer overlaps a portion of the plurality of second-type elements as viewed in the third direction.

13. The magnetic sensor according to claim 1, further comprising:
an electrode layer formed of a conductive material, wherein
the plurality of magnetoresistive elements include a plurality of specific elements electrically connected to the electrode layer, and
of the plurality of specific elements, multiple elements are arrayed both in the first direction and the second direction.

14. The magnetic sensor according to claim 13, further comprising:
a plurality of via electrodes each formed of a conductive material, wherein
the plurality of specific elements are connected to the electrode layer via the plurality of via electrodes.
